(19) United States
(12) Patent Application Publication
(10) Pub. No.: US 2017/0263638 A1
(43) Pub. Date: Sep. 14, 2017

(54) SEMICONDUCTOR MEMORY DEVICE

(71) Applicant: KABUSHIKI KAISHA TOSHIBA, Tokyo (JP)

(72) Inventor: Nobuaki OKADA, Yokohama Kanagawa (JP)

(21) Appl. No.: 15/346,562

(22) Filed: Nov. 8, 2016

(30) Foreign Application Priority Data
Mar. 11, 2016 (JP) 2016-048890

(51) Int. Cl. H01L 27/11582; H01L 23/522; H01L 23/528; H01L 27/11556

(52) U.S. Cl. CPC H01L 27/11582; H01L 27/11556; H01L 23/5226; H01L 23/528

(57) ABSTRACT

A semiconductor memory device includes a first region including first memory cells and first wiring layers, and a second region including second memory cells and second wiring layers, the first and second wiring layers each including a first level wiring layer and a second level wiring layer. End portions of the first and second wiring layers extend in a first direction into a wiring pullout region, such that each of the first and second level wiring layers has an exposed upper surface. The exposed upper surfaces of the first and second level wiring layers are adjacent in a second direction crossing the first direction. First and second contacts are arranged respectively on the exposed surfaces of the first and second level wiring layers, such that the first contacts and the second contacts are arranged respectively along first and second lines extending in the first direction

### CROSS-REFERENCE TO RELATED APPLICATION

This application is based upon and claims the benefit of priority from Japanese Patent Application No. 2016-048890, filed Mar. 11, 2016, the entire contents of which are incorporated herein by reference.

### FIELD

Embodiments described herein relate generally to a semiconductor memory device.

### BACKGROUND

A semiconductor memory device with stacked memory cells is generally known.

### DESCRIPTION OF THE DRAWINGS

FIG. 1 is a block diagram of a semiconductor memory device according to a first embodiment.

FIG. 2 is a circuit diagram of a memory cell array provided in the semiconductor memory device according to the first embodiment.

FIG. 3 is a circuit diagram of a row decoder provided in the semiconductor memory device according to the first embodiment.

FIG. 4 is a plan view of the layout of the memory cell array provided in the semiconductor memory device according to the first embodiment.

FIG. 5 is a plan view of the layout in a cell region of the memory cell array provided in the semiconductor memory device according to the first embodiment.

FIG. 6 is a cross-sectional view taken along the line VI-VI of FIG. 4.

FIG. 7 is a perspective view of a stacked structure of word lines and select gate lines of the memory cell array in the semiconductor memory device according to the first embodiment.

FIG. 8 is a plan view of the layout in a wiring pullout region of the memory cell array provided in the semiconductor memory device according to the first embodiment.

FIG. 9 is a cross-sectional view taken along the line IX-IX of FIG. 4.

FIG. 10 is a cross-sectional view taken along the line X-X of FIG. 4.

FIG. 11 is a plan view of the layout illustrating a wiring pullout region of a comparison example.

FIG. 12 is a plan view of the layout in the wiring pullout region of a memory cell array provided in a semiconductor memory device according to a second embodiment.

FIG. 13 is a plan view of the layout illustrating a wiring pullout region of a comparison example.

FIG. 14 is a plan view of the layout illustrating a wiring pullout region of a comparison example.

FIG. 15 is a plan view of the layout in the wiring pullout region of a memory cell array provided in a semiconductor memory device according to a third embodiment.

FIG. 16 is a plan view of the layout illustrating a wiring pullout region.

FIG. 17 is a plan view of the layout illustrating a comparison example in the wiring pullout region of a comparison example.

FIG. 18 is a plan view of the layout of a memory cell array provided in a semiconductor memory device according to a fourth embodiment.

FIG. 19 is a plan view of the layout of the memory cell array provided in the semiconductor memory device according to the fourth embodiment.

FIG. 20 is a cross-sectional view taken along the line XX-XX of FIG. 18.

FIG. 21 is a plan view of the layout of a memory cell array provided in a semiconductor memory device according to a fifth embodiment.

FIG. 22 is a cross-sectional view taken along the line XXII-XXII of FIG. 21.

### DETAILED DESCRIPTION

In general, according to one embodiment, there is provided a semiconductor memory device capable of being manufactured with improved yield.

According to one embodiment, a semiconductor memory device includes a memory cell array that includes a first region including a plurality of first memory cells and a plurality of first wiring layers stacked over a semiconductor substrate, and a second region including a plurality of second memory cells and a plurality of second wiring layers stacked over the semiconductor substrate, the first and second wiring layers each including a wiring layer at a first level above the substrate and a wiring layer at a second level above the substrate. End portions of each of the first wiring layers and the second wiring layers extend in a first direction into a wiring pullout region, such that each of the first and second level wiring layers of both the first and second wiring layers has an exposed upper surface. In each of the first wiring layers and the second wiring layers, the exposed upper surfaces of the first and second level wiring layers are adjacent in a second direction crossing the first direction. First and second contacts arranged respectively on the exposed surfaces of the first and second level wiring layers of each of the first and second wiring layers, such that the first contacts and the second contacts are arranged respectively along first and second lines that extend in the second direction and are spaced apart in the first direction.

Hereinafter, embodiments will be described with reference to the drawings, which are schematically illustrated. Each embodiment depicts an example of a device and a method for embodying a technical spirit of the invention.

In the following description, the common reference codes are attached to elements having the same function and the same structure. Some reference codes employ a “numeral” or a “combination of hyphen and numeral” as a suffix. Such reference code employ the suffix to distinguish between elements having the same structure. When there is no need to distinguish between such elements, these elements are referred to by the reference code without the suffix.

### [1] First Embodiment

Hereinafter, a semiconductor memory device according to a first embodiment will be described.

[1-1] Structure of First Embodiment

At first, a structure of a semiconductor memory device according to the first embodiment will be described.

[1-1-1] Entire Structure of Semiconductor Memory Device 1

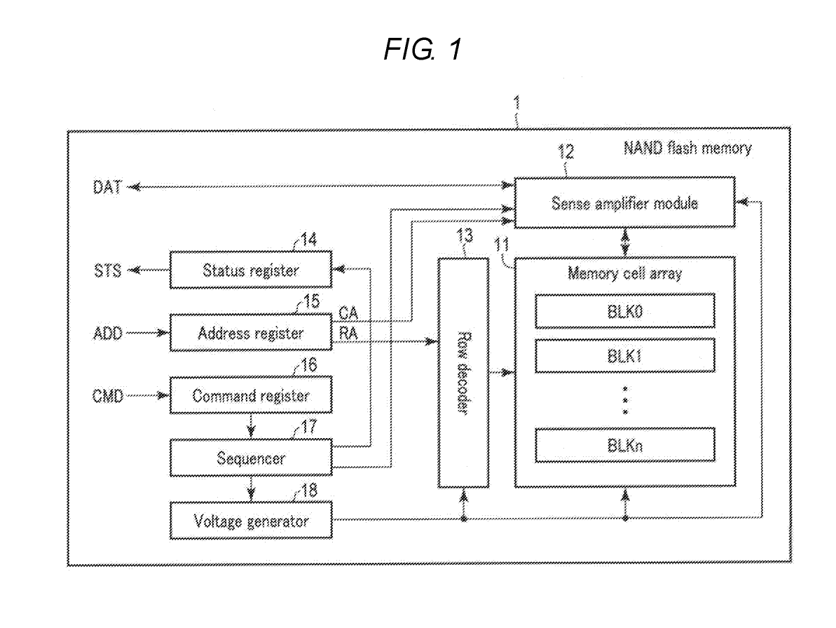

At first, with reference to FIG. 1, the entire structure of the semiconductor memory device will be described. FIG. 1 illustrates a block diagram of the semiconductor memory device 1. As illustrated in FIG. 1, the semiconductor memory device 1 includes a memory cell array 11, a sense amplifier module 12, a row decoder 13, a status register 14, an address register 15, a command register 16, a sequencer 17, and a voltage generator 18.

The memory cell array 11 includes blocks BLK0 to BLKn (n is a natural number of 1 and more). The block BLK is a group of a plurality of nonvolatile memory cells at an intersection of bit lines and word lines and it is, for example, the unit of erasing data.

The sense amplifier module 12 senses data DAT read from the memory cell array 11 and outputs the read data DAT to an external controller as needed. The sense amplifier module 12 also applies a voltage to a bit line according to the written data DAT received from the controller.

The row decoder 13 selects a word line corresponding to a memory cell targeted for reading and writing. The row decoder 13 applies each desired voltage to a selected word line and a non-selected word line.

The status register 14 holds status information STS of the semiconductor memory device 1.

The address register 15 holds address information ADD transmitted from the controller. The address register 15 transmits a column address signal CA and a row address signal RA included in the address information ADD to the sense amplifier module 12 and the row decoder 13.

The command register 16 holds a command CMD transmitted from the external controller. The command register 16 transmits the command CMD to the sequencer 17.

The sequencer 17 controls the operation of the entire semiconductor memory device 1.

The voltage generator 18 generates a voltage for the memory cell array 11, the sense amplifier module 12, and the row decoder 13.

[1-1-2] Circuit Structure of Memory Cell Array 11 and Row Decoder 13

Next, the circuit structure of the memory cell array 11 and the row decoder 13 will be described sequentially.

[1-1-2-1] Circuit Structure of Memory Cell Array 11

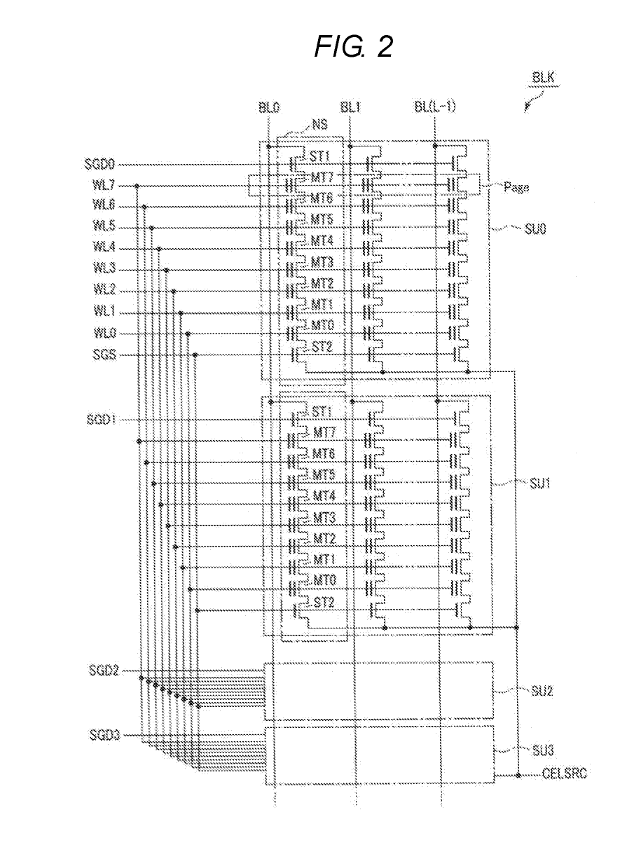

At first, the circuit structure of the memory cell array 11 will be described. As described in the above, the memory cell array 11 includes a plurality of blocks BLK. The blocks BLK include a plurality of memory cell transistors that operate as nonvolatile memory cells. FIG. 2 is a circuit diagram of one of the blocks BLK.

As illustrated in FIG. 2, the block BLK includes, for example, four string units SU (SU0 to SU3). Each string unit SU is provided with a different select gate line SGD. The string units SU share a plurality of word lines WL, select gate line SGS, and a source line CELSRC. Each string unit SU includes a plurality of NAND strings NS.

Each NAND string NS is provided respectively for each of the bit lines BL0 to BL (L−1) (where (L−1) is a natural number of 1 and more); for example, the NAND strings NS includes eight memory cell transistors MT (MT0 to MT7) and select transistors ST1 and ST2.

The memory cell transistor MT includes a control gate and a charge storage layer and holds data in a nonvolatile manner. The select transistors ST1 and ST2 select a string unit SU during the writing operation.

In each of the NAND strings NS, the memory cell transistors MT0 to MT7 are coupled in series between the source of the select transistor ST1 and the drain of the select transistor ST2. Further, the drain of the select transistor ST1 is coupled to the corresponding bit line BL. In other words, in a block BLK, the NAND strings NS on the same column are coupled to the corresponding bit lines BL in common. Further, similarly, in the blocks BLK, the NAND strings NS on the same column are coupled to the corresponding bit line BL in common.

In the string units SU0 to SU3, the gates of the select transistors ST1 are respectively coupled to the select gate lines SGD0 to SGD3 in common. In the same block BLK, the control gates of the memory cell transistors MT0 to MT7 are respectively coupled to the word lines WL0 to WL7 in common, the gates of the ST2 are coupled to the select gate lines SGS in common, and the sources of the select transistors ST2 are coupled to the source line CELSRC in common.

In the above structure, a set of one bit data held by a plurality of the memory cells coupled to the same word line WL is referred to as a “page”. The “page” can be defined as a part of a memory space formed by the memory cells coupled to the same word line.

Here, the number of the string units SU included in one block BLK and the number of the memory cell transistors MT included in one NAND string NS are not limited to the numbers given in the above examples but may be any number. In the same block BLK, the select gate line SGS may be provided in every string unit SU.

[1-1-2-2] Circuit Structure of Row Decoder 13

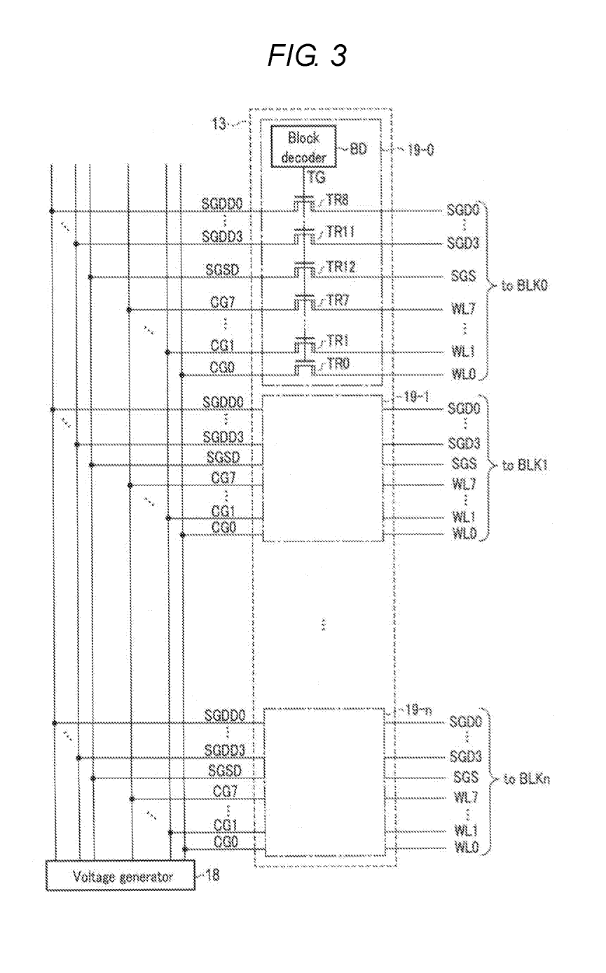

With reference to FIG. 3, the circuit structure of the row decoder 13 will be described. FIG. 3 illustrates the circuit structure of the row decoder 13. In the following description, the row decoder 13 will be described together with the connection relationship with the voltage generator 18.

As illustrated in FIG. 3, the row decoder 13 includes transfer units 19-0 to 19-n corresponding to the blocks BLK0 to BLKn, respectively. The transfer unit 19 selects the corresponding block BLK during the writing operation. The transfer unit 19 includes a plurality of high breakdown voltage n-channel MOS transistors TR and a block decoder BD.

The transistors TR are respectively provided for the word lines WL and the select gate lines SGD and SGS. The transistor TR transfers a voltage supplied from the voltage generator 18 through various signal lines to the corresponding block BLK. Here, the signal lines corresponding to the word line WL and the select gate lines SGD and SGS are respectively referred to as a signal line CG and signal lines SGDD and SGSD. These signal lines are shared among the transfer units 19. The voltage generator 18 decodes the page address of the row address signal RA and applies a desired voltage to the various signal lines based on the decoded page address.

More specifically, in the transistors TR0 to TR7, one ends thereof are coupled to the word lines WL0 to WL7 and the other ends thereof are coupled to the signal lines CG0 to CG7. In the transistors TR8 to TR11, one ends thereof are coupled to the select gate lines SGD0 and SGD3 and the other ends thereof are coupled to the signal lines SGDD0 to SGDD3. In the transistor TR12, one end is coupled to the select gate line SGS and the other end is coupled to the signal line SGSD. The gates of these transistors TR0 to TR12 are coupled to the transfer gate line TG in common.

The block decoder BD decodes the block address included in the row address signal RA received from the address register 15 and applies a voltage to the transfer gate line TG based on the decoded block address. Specifically, in various operation, the block decoders BD corresponding to the selected and non-selected blocks BLK apply voltages of “H” level and “L” level to the transfer gate lines TG. The transfer unit 19 corresponding to the selected block BLK turns on the transistors TR and the transfer unit 19 corresponding to the non-selected block BLK turns off the transistors TR.

For example, when the block BLK0 is selected, the transistors TR0 to TR12 included in the transfer unit 19-0 are turned on and the transistors TR0 and TR12 included in the other transfer units 19 are turned off. According to this, the word lines WL and the select gate lines SGD and SGS in the block BLK0 are respectively electrically coupled to various signal lines and the word lines WL and the select gate lines SGD and SGS in the other blocks BLK are electrically isolated from the various signal lines.

As mentioned above, in the respective transfer units 19 in the row decoder 13, the transistors TR corresponding to the respective word lines WL are provided in common among the string units SU and the transistors TR corresponding to the respective select gate lines SGD are provided independently for every string unit SU.

Here, the transistors TR corresponding to the word lines WL may be formed differently from the transistors TR corresponding to the select gate lines SGD and SGS. For example, according to a difference in the voltages supplied to the various signal lines, a breakdown voltage of the corresponding transistor TR can be changed.

In the above description, although the case of the voltage generator 18 decoding the page address has been described, it is not limited to this. For example, a driver circuit may be provided between the voltage generator 18 and the row decoder 13 and the driver circuit may decode the page address, such that each desired voltage may be applied to the various signal lines.

[1-1-3] Plan Surface and Cross Sectional Structure of Memory Cell Array 11

Next, a plan surface and cross sectional structure of the memory cell array 11 will be described. In the below, the entire structure of the memory cell array 11 will be described and then, the detailed structure of each divided region of the memory cell array 11 will be described.

[1-1-3-1] Entire Structure of Memory Cell Array 11

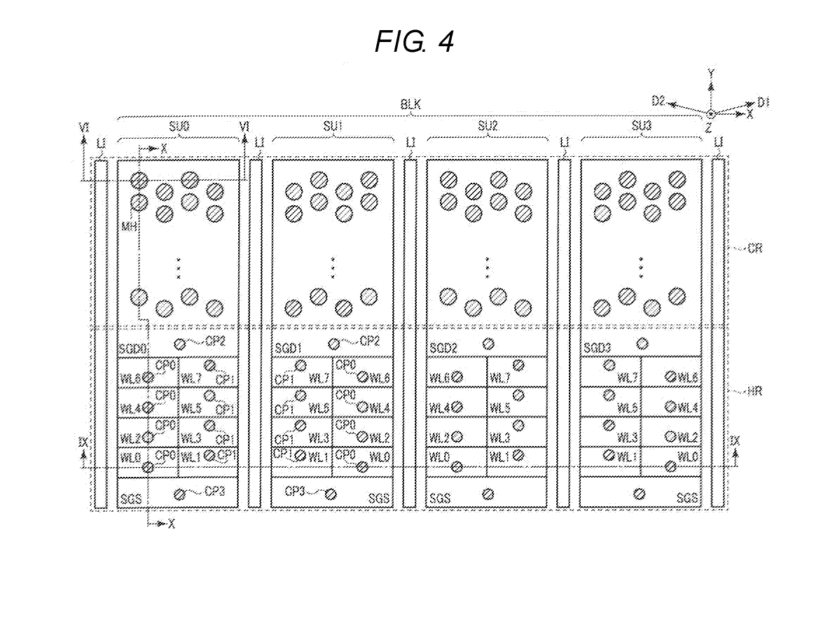

At first, with reference to FIG. 4, the entire structure of the memory cell array 11 will be described. FIG. 4 illustrates a plan view of one block BLK included in the memory cell array 11. In FIG. 4, arrows indicating X direction, Y direction, and Z direction mutually cross each other at right angles and the Z direction corresponds to a perpendicular direction to the semiconductor substrate surface.

As illustrated in FIG. 4, a plurality of string units SU are provided in the memory cell array 11 along the X direction. The string unit SU is formed in a stacked structure including the select gate line SGS, the word lines WL0 to WL7, and the select gate line SGD together with alternating layers of the insulating films.

In an area between the adjacent string units SU in the X direction, there is provided a slit without the stacked structure, in which the insulating film is embedded. The insulating film within the slit isolates the above-described wiring layers between the string units SU. Further, in the slit, for example, a contact plug LI is provided planar shape and extending along the Y direction and the Z direction.

As mentioned above, the string unit SU can be defined as an area obtained by dividing one block BLK by the contact plugs LI. Alternatively, it may be defined as an area obtained by dividing the stacked structure by the slits. In the embodiment, the adjacent string units SU are formed in line symmetry with the Y direction as an axis of symmetry.

The string unit SU roughly includes a cell region CR and a pullout region HR. The cell region CR is an area where memory cells are formed in the stacked structure, actually working as a data holding area, whereas the pullout region HR is an area where contact plugs for coupling the wiring layers formed in the string unit SU to the row decoder 13 are provided. The cell region CR and the pullout region HR are adjacent to each other in the Y direction.

In short, the word lines WL and the select gate lines SGD and SGS are provided along the Y direction and ends thereof are drawn out to the pullout region HR. Then, the word lines WL and the select gate lines SGD and SGS are coupled to the wiring layer for coupling to the row decoder 13, in the pullout region HR.

[1-1-3-2] Plan Surface and Cross Sectional Structure of Cell Region

Next, the detailed structure of the cell region CR will be described.

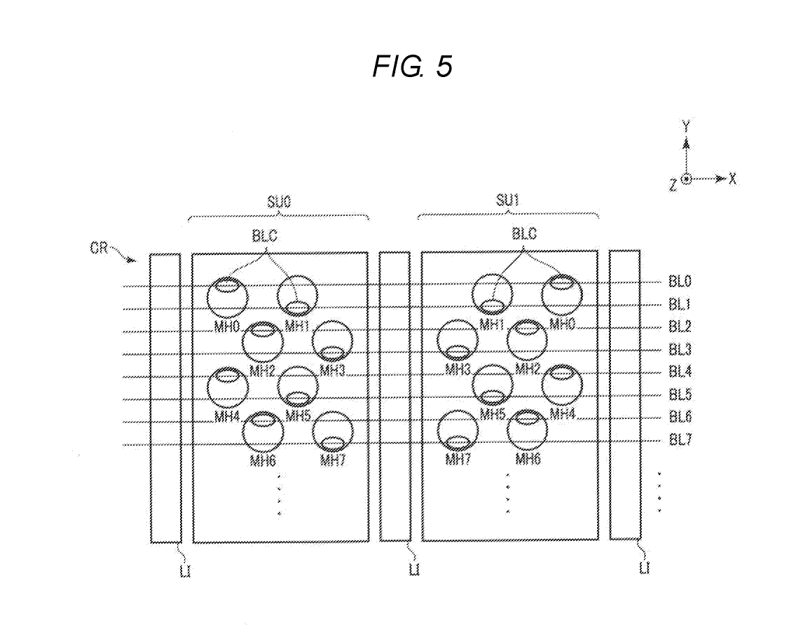

At first, with reference to FIG. 5, a plan view of the cell region CR will be described in more detail. FIG. 5 illustrates the plan view in the cell region CR of the string units SU0 and SU1.

As illustrated in FIG. 5, in each of the string units SU, a plurality of semiconductor pillars MH are provided within and extending through the stacked structure where the select gate line SGS, the word lines WL0 to WL7, and the select gate line SGD are provided alternately with the insulating films. The semiconductor pillars MH are arranged in the X direction and the Y direction, for example, in a staggered shape of four rows. One semiconductor pillar MH corresponds to the above mentioned one NAND string NS and one bit line BL is coupled to one semiconductor pillar MH. Specifically, the bit lines BL0 to BL7 are respectively coupled to the semiconductor pillars MH0 to MH7 through the bit line contacts BLC.

The respective bit lines BL are provided along the X direction. In the case of this example, the semiconductor pillars MH are arranged in a staggered shape of four rows, and for example, two bit lines BL pass over the semiconductor pillar MH. In short, the bit line contact BLC is provided between the semiconductor pillar MH and the corresponding bit line BL.

The number of the bit lines BL passing over the semiconductor pillar MH is not limited to two. In some embodiments, three and more bit lines BL may pass over the semiconductor pillar MH.

Further, the contact plug LI is coupled, for example, to the source line CELSRC or the well line CPWELL, which is not illustrated. In some embodiments, all of the contact plugs LI are coupled to the source line CELSRC, and only some of them are coupled to the well line CPWELL.

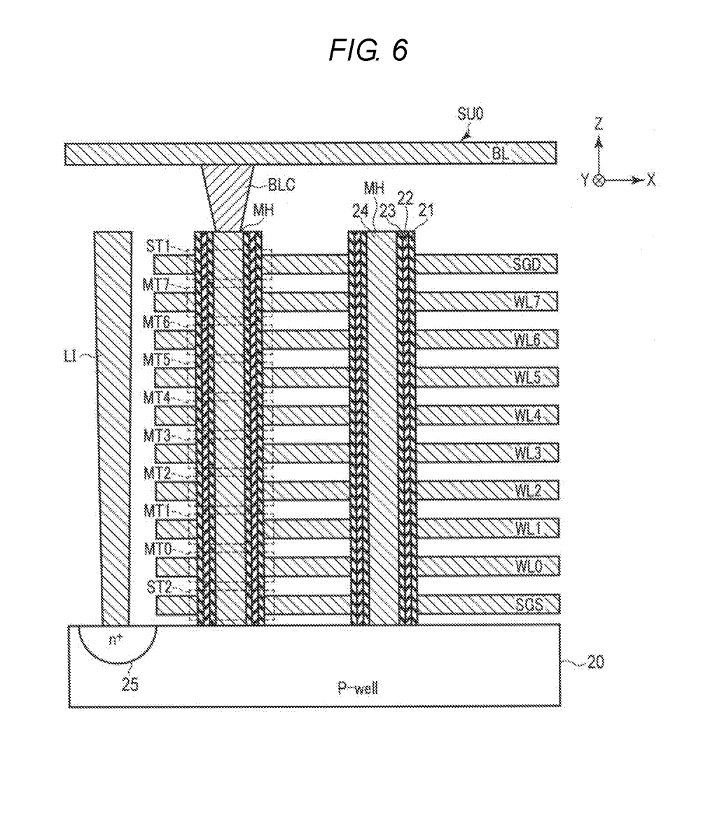

Next, with reference to FIG. 6, the cross sectional structure of the cell region CR will be described. FIG. 6 illustrates the cross section taken along the line VI-VI of FIG. 4. To simplify the following description, an interlayer insulating film is omitted in FIG. 6.

As illustrated in FIG. 6, the wiring layers corresponding to the select gate line SGS, the word lines WL0 to WL7, and the select gate line SGD are sequentially stacked in this order from the bottom on the P-type well region 20 of a semiconductor substrate, respectively with the interlayer insulating films interposed therebetween. The word lines WL and the select gate lines SGD and SGS are formed in a plate shape extending in the X direction and in the Y direction.

The semiconductor pillar MH is formed in the Z direction from the top surface of the select gate line SGD down to the upper surface of the P-type well region 20. In other words, the semiconductor pillar MH penetrates the select gate line SGD, the word lines WL7 to WL0, and the source line SGS. On the lateral surface of an opening for the semiconductor pillar MH, a block insulating film 21, an insulating film (charge storage layer) 22, and a tunnel oxide film 23 are sequentially formed. Further, a semiconductor material 24 including a conductive material is embedded inwardly from the tunnel oxide film 23 to form the semiconductor pillar MH. Alternatively, a film of the semiconductor material 24 is formed inwardly of the inner surface of the tunnel oxide film 23 and an insulator may be embedded further inwardly to form the semiconductor pillar MH.

A wiring layer corresponding to the bit line BL is formed over the select gate line SGD. The bit line contact BLC including a conductive material is formed between the bit line BL and the corresponding semiconductor pillar MH.

The contact plug LI contains a conductive material and is coupled to an n⁺ dopant diffusion region 25 formed on the surface of the P-type well region 20.

According to the above structure, the NAND string NS is formed along the semiconductor pillar MH. Specifically, intersections of the select gate lines SGD and SGS with the semiconductor pillar MH correspond to locations of the select transistors ST1 and ST2, respectively. Similarly, each intersection of the word lines WL and the semiconductor pillar MH corresponds to the location of each memory cell transistor MT. The source line CELSRC (not illustrated) is coupled to the semiconductor pillars MH through the contact plug LI and the P-type well region 20.

In the following description, the word lines WL and the select gate lines SGD and SGS are referred to as the wiring layers formed for each of the string units SU, excluding the contact plug and other wiring layers electrically coupled to these wiring layers.

[1-1-3-3] Plan Surface of Cross Sectional Structure of Wiring Pullout Region HR

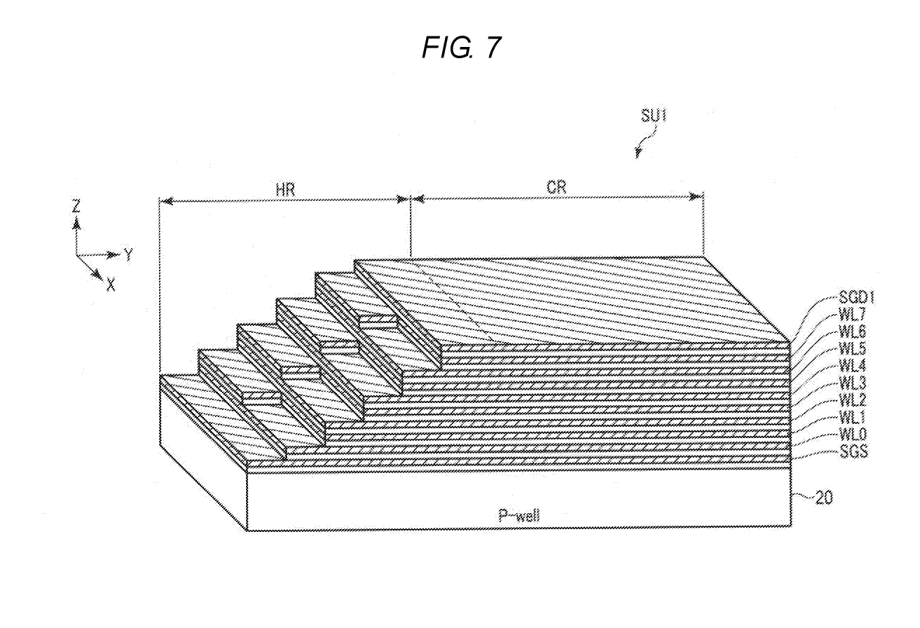

Next, the detailed structure in the pullout region HR will be described. FIG. 7 is a perspective view of the stacked structure including the word lines WL and the select gate lines SGD and SGS with the alternating insulating films in one string unit SU.

As illustrated, the wiring layers including the word lines WL and the select gate lines SGD and SGS completely overlap with each other in the cell region CR.

In the pullout region HR, similarly to the cell region CR, the select gate line SGS, the word lines WL0 to WL7, and the select gate line SGD are sequentially stacked respectively with the interlayer insulating films interposed therebetween on the P-type well region 20 of the semiconductor substrate. The end portion of the lower wiring layer, however, has an area not overlapping with the upper wiring layer. As a result, the end portions of the respective wiring layers in the pullout region HR are formed in a step shape.

Specifically, the select gate line SGS forms a step in the Y direction with the word line WL0 that is the wiring layer one upper than the line SGS, and the word line WL0 forms a step in the X direction with the word line WL1 that is the wiring layer one upper than the word line WL0. The word lines WL0 and WL1 respectively form a step in the Y direction with the word lines WL2 and WL3. Similarly, the word lines WL2 and WL3 respectively forma step in the Y direction with the word lines WL4 and WL5, and the word lines WL4 and WL5 respectively form a step in the Y direction with the word lines WL6 and WL7. Further, each of the word lines WL6 and WL7 forms a step in the Y direction with the select gate line SGD.

In the thus formed pullout region HR, the word lines WL form a step of one wiring layer in the X direction and form a step of two wiring layers in the Y direction. In the following description, an area not overlapping with the upper layer in each of the wiring layers is referred to as a “pullout portion”.

The respective pullout portions of the wiring layers are provided with the respective contact plugs CP, as illustrated in FIG. 4. Specifically, in each of the string units SU, the contact plugs CP0 are respectively provided on the pullout portions of the word lines WL0, WL2, WL4, and WL6 arranged at one side of the X direction and the contact plugs CP1 are respectively provided on the pullout portions of the word lines WL1, WL3, WL5, and WL7 at the other side of the X direction.

In each of the string units SU, the contact plugs CP provided on the pullout portion of the word lines WL arranged in the X direction are offset in the Y direction. Specifically, in the string unit SU0, the contact plugs CP0 and CP1 are arranged orthogonally to the Z direction and along a first direction D1 crossing the X direction and the Y direction. The pullout portion of the select gate lines SGD and SGS are respectively provided with the contact plugs CP2 and CP3. In the embodiment, the string unit SU1 is in line symmetry to the string unit SU0 with respect to the Y direction; therefore, in the string unit SU1, the contact plugs CP0 and CP1 are arranged along a second direction D2 in line symmetry to the first direction D1 with the Y direction as an axis of symmetry.

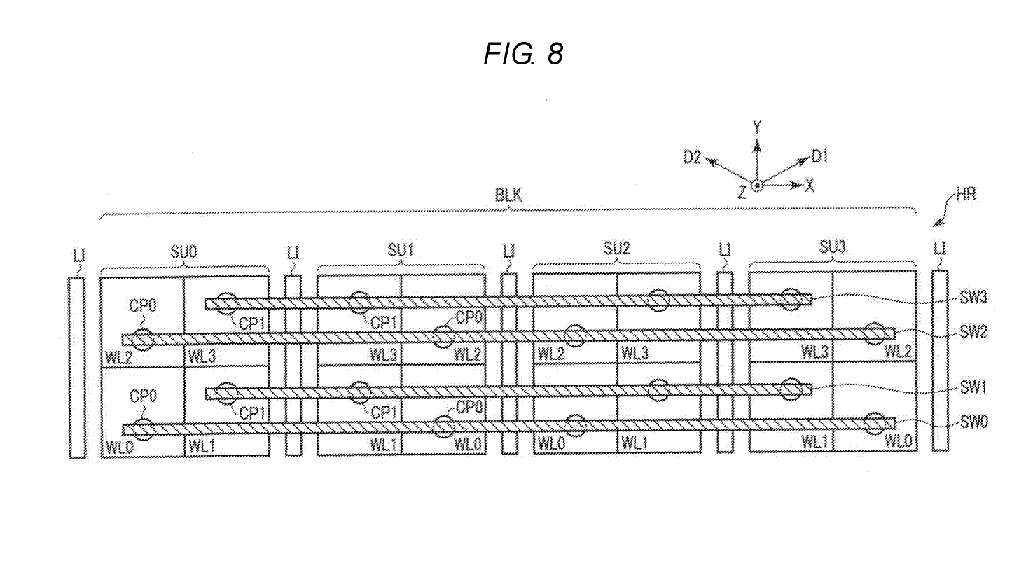

With reference to FIG. 8, the layout of the pullout region HR will be described in more detail. FIG. 8 partially illustrates the pullout portion of the word lines WL0 to WL3 in the four string units SU0 to SU3.

In the pullout region HR, as illustrated in FIG. 8, a plurality of short wirings SW are provided. The short wiring SW electrically couples the corresponding word line WL across the string units SU in common and is coupled to the row decoder through a wiring layer not illustrated. Here, the “corresponding word line WL” shows the line formed in the same layer, of the wiring layers operating as the word lines WL, in the same block BLK. The “corresponding word line WL” can be defined as the wiring layer having the same number when counting the layers from the P-type well region 20, the wiring layer positioned at the same level of height above the P-type well region 20, or the wiring layer where the same potential has to be applied for the operation of the semiconductor memory device 1.

More specifically, the wiring SW0 is provided to couple the word line WL0 across the string units SU in common. The wiring SW1 is provided to couple the word line WL1 across the string units SU in common. Similarly, the wirings SW2 and SW3 are respectively provided to couple the word lines WL2 and WL3 across the string units SU in common. The other wirings SW have the same structure.

The contact plugs CP are arranged between the short wiring SW and the corresponding word line WL, and the corresponding word line WLs are electrically connected through the contact plugs CP. The contact plugs CP used for the connection of the corresponding word line WL are arranged along a straight line in the X direction. In other words, the contact plugs CP used for the connection of the corresponding word line WL are arranged along a straight line that is parallel to the bit line BL direction (X direction).

More specifically, the contact plugs CP0 are provided between the wiring SW0 and the word line WL0 across the string units SU. The contact plugs CP1 are provided between the wiring SW1 and the word line WL0 across the string units SU. Similarly, the contact plugs CP0 and CP1 are provided between the wirings SW2 and SW3 and the word lines WL2 and WL3 across the string units SU.

In the above structure, a plurality of wirings SW are provided along the X direction. In short, the wirings SW are provided in parallel to the bit line BL direction. Further, the wiring SW is provided, for example, in a shape of straight line. Here, the “straight line shape” means the shape of a schematic straight line including variations such as roughness in the formed wirings. Further, the “arranged along the straight line” means that something is not only arranged on the completely straight line but also may be deviated slightly from the straight line”. For example, the contact plugs CP are considered to be “arranged along the straight line” in the X direction, so long as the contact plugs CP are arranged to make the short wirings SW formed on the corresponding contact plugs CP into a shape of a straight line. By contrast, contact plugs CP “offset” from a straight line are arranged so that the short wiring SW formed on such contact plugs CP cannot be made to be in a shape of a straight line.

Here, between the contact plugs LI, the number of the pullout portions formed by the word lines WL in the bit line BL direction (X direction) is equal to the number of the wiring layers provided in a straight line shape, overlapping the pullout portions aligned in the bit line BL direction. For example, as illustrated in FIG. 8, between the contact plugs LI, when the two pullout portions are provided by the word lines WL0 and WL1 in the bit line BL direction, two short wirings SW are provided to electrically connect the word lines WL across the string units SU in the block BLK.

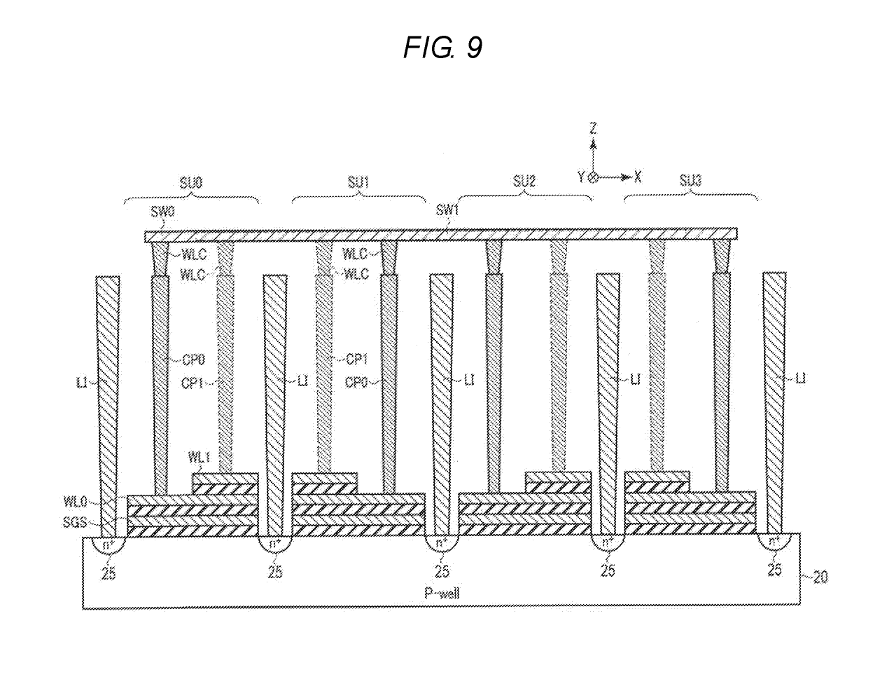

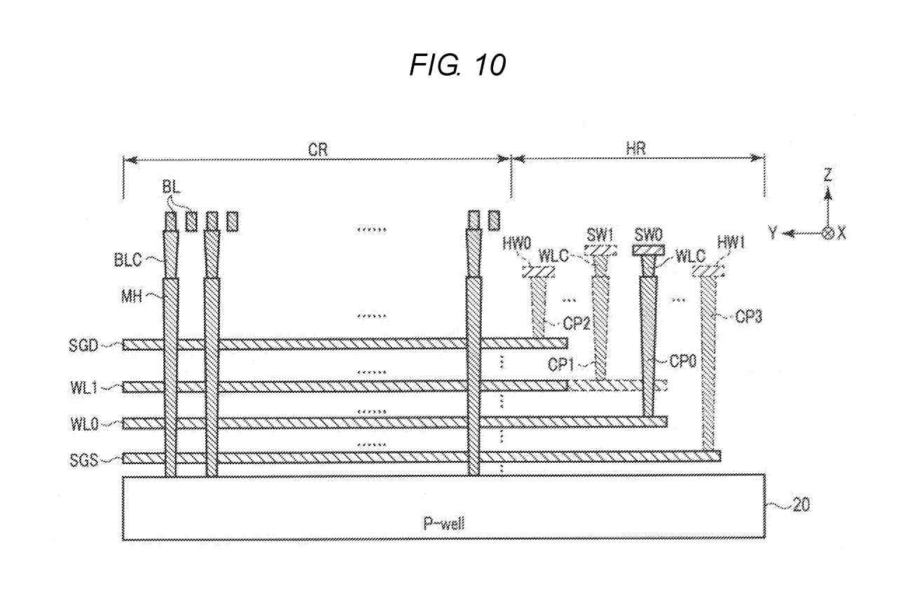

Next, with reference to FIGS. 9 and 10, the cross sectional structure of the pullout region HR will be described. FIG. 9 is a cross section taken along the line IX-IX of FIG. 4, including the pullout portions of the word lines WL0 and WL1. FIG. 10 illustrates the cross section taken along the line X-X of FIG. 4.

As illustrated in FIG. 9, one string unit SU is arranged between the two contact plugs LI. In each of the string units SU, the select gate line SGS and the word lines WL0 and WL1 are sequentially stacked on the P-type well region 20 respectively with the interlayer insulating films interposed therebetween. The word lines WL0 and WL1 form a step in the X direction, such that is not overlapped by the upper wiring layer. In other words, in the region HR, by narrowing the width of the end portion of the word line WL1 more than the width of the end portion of the word line WL0, the pullout portion of the word line WL0 is provided. In the cell region CR, the width of the word line WL0 is equal to the width of the word line WL1 and the word lines WL0 and WL1 overlap each other.

Further, the contact plugs CP0 and CP1 including the conductive material are formed, for example, up to the layer of the same level of height. Further, as illustrated in FIG. 10, the contact plugs CP0 and CP1 are respectively arranged on the word lines WL0 and WL1 at a distance in the Y direction.

As illustrated in FIG. 9, the short wirings SW0 and SW1 are formed above the contact plugs LI. The word line contacts WLC including the conductive material are formed between the short wiring SW0 and the contact plugs CP0 corresponding to the word line WL0 in each of the string units SU. Similarly, the word line contacts WLC including the conductive material are formed between the short wiring SW1 and the contact plugs CP1 corresponding to the word line WL1 in each of the string units SU.

The n⁺ dopant diffusion areas 25 are formed at regular intervals on the surface of the P-type well region 20 in the X direction. Then, the contact plugs LI are respectively formed in the n⁺ dopant diffusion areas 25 and the source line CELSRC is formed over the contact plugs LI.

As illustrated in FIG. 10, the select gate line SGD is coupled to the wiring layer corresponding to the wiring HW0 through the contact plug CP2, and the select gate line SGS is coupled to the wiring layer corresponding to the wiring HW1 through the contact plug CP3. The wirings HW0 and HW1 are respectively the wirings for coupling the select gate lines SGD and SGS to the row decoder 13.

In the above structure, the short wiring SW is formed, for example, in the wiring layer between the upper end of the semiconductor pillar MH and the bit line BL. The wiring HW is formed, for example, in the wiring layer between the short wiring SW and the upper end of the semiconductor pillar MH.

The wiring layers where the short wiring SW and the wiring HW are formed are not limited to the above. For example, the short wiring SW and the bit line BL may be formed in the same wiring layer, or the short wiring SW and the wiring HW may be formed in the same wiring layer. In FIG. 10, the upper ends of the semiconductor pillars MH are aligned with the lower end of the wiring layer corresponding to the wiring HW; however, it is not limited to this. For example, the wiring HW may be formed in the wiring layer between the upper ends of the semiconductor pillars MH and the short wiring SW.

The coupling method of the short wiring SW and the contact plug CP is not limited to the above. For example, the short wiring SW may be directly coupled to the contact plug CP without providing the word line contact WLC. In this case, the upper end of the contact plug CP is formed higher than the upper end of the contact plug LI. Similarly, the coupling method of the wiring HW and the contact plug CP is not limited to the above but they may be coupled together through a plurality of the contact plugs CP.

[1-2] Effect of First Embodiment

Next, the effect of the first embodiment will be described. The semiconductor memory device 1 according to the embodiment can improve the yield. Hereinafter, the details of the effect will be described.

In the semiconductor memory device with the memory cells stacked, the word lines corresponding to the respective layers of the memory cells are formed in a plate shape. These stacked word lines are formed in steps of several rows in the end portion of the cell array, hence to be pulled out and are coupled to a peripheral circuit through the contact plugs coupled to the pullout portions.

When each of the blocks forming the memory cell array includes a plurality of string units, a wiring layer corresponding to a word line can be isolated between the respective string units formed within the block. In this structure, the word lines formed in the respective strings units within the block are electrically connected through the different wiring layer.

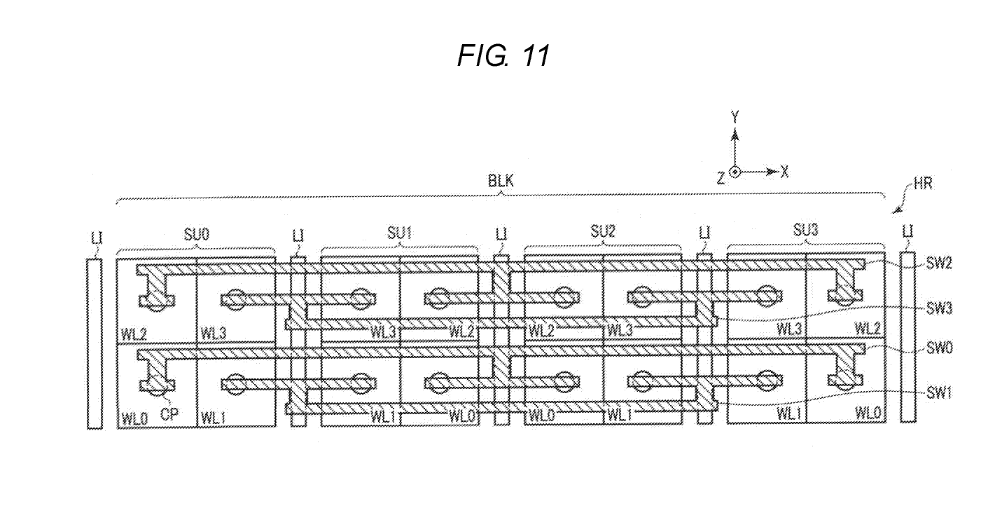

For example, when the pullout portions of the word lines WL are formed in a step of two rows, the structure indicated in FIG. 11 may be used in a comparative example. In this case, the contact plugs CP corresponding to the word lines WL (for example, WL0 and WL1) that form a step in the X direction (bit line direction) are arranged along a straight line in the X direction. The short wirings SW (for example, SW0 and SW1) coupled to these contact plugs CP are provided out of contact with each other, as illustrated in FIG. 11. More specifically, the short wirings SW0 and SW1 are arranged to sandwich the contact plugs CP arranged along the straight line. The short wirings SW0 and SW1 are coupled to the corresponding contact plugs CP from both sides in the Y direction. In other words, in the case of the structure as illustrated in FIG. 11, in order that the pullout portion forms the two short wirings SW corresponding to the two adjacent word lines in the bit line direction, a margin for avoiding a connection with the non-corresponding contact plug CP is necessary, in addition to the wiring width for the short wiring SW.

According to the first embodiment, in the semiconductor memory device 1 with the pullout portions of the word lines WL formed in a step shape of two rows, the contact plugs CP provided in the pullout portions of the word lines WL formed in the step shape in the bit line direction are offset in the word line direction. The contact plugs CP arranged in the bit line direction as illustrated in FIG. 8 do not include the contact plugs CP corresponding to the different word line WL. In short, the short wirings SW can be formed in a straight line shape.

According to this, the design of the short wirings SW can be simplified. When the short wirings SW can be formed in a repeating pattern of a straight line shape, as illustrated in FIG. 8, the difficulty of patterning during lithography decreases. In other words, the semiconductor memory device 1 according to the embodiment can suppress the defect caused by during lithography at the manufacturing time, hence to improve the yield.

According to the semiconductor memory device 1 according to the embodiment, when designing the layout of the short wirings SW, it is not necessary to consider a margin for avoiding the non-corresponding contact plugs CP. In other words, this embodiment reduces the concern about restricting the width of the word line WL in the pullout portion in the word line direction from the viewpoint of the processing by the short wiring SW. According to this, the semiconductor memory device 1 according to the embodiment can suppress an increase in chip area.

The semiconductor memory device 1 according to the embodiment can achieve the short wiring SW in one wiring layer. The semiconductor memory device 1 according to the embodiment can assure the design margin for the wirings of coupling the word lines WL to the row decoder 13.

### [2] Second Embodiment

A semiconductor memory device 1 according to a second embodiment will be described. In the second embodiment, the word line WL in the pullout region HR described in the first embodiment is changed from the step shape of two rows to the step shape of three rows. Hereinafter, a different point from the first embodiment will be described.

[2-1] Structure of Second Embodiment

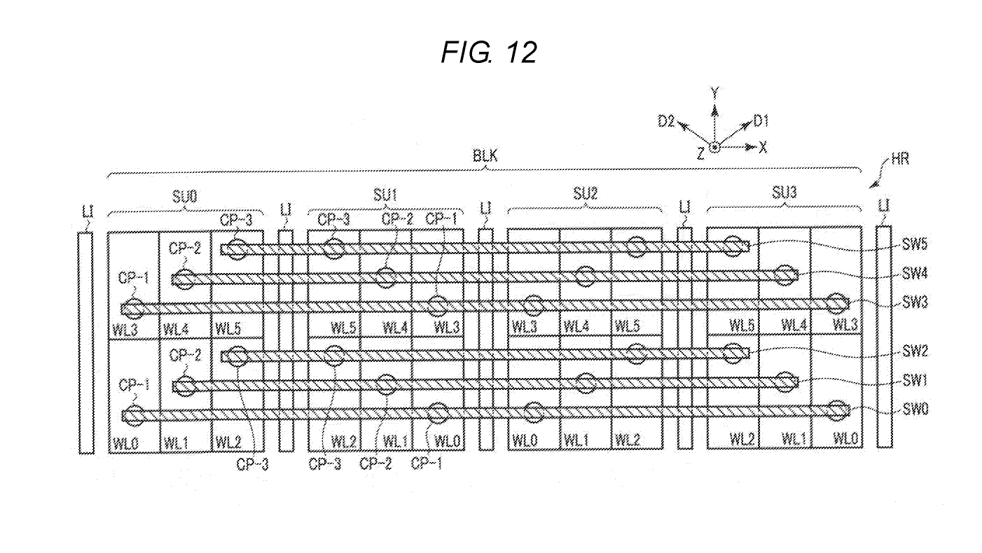

At first, with reference to FIG. 12, the plan layout of the memory cell array 11 in the pullout region HR will be described. FIG. 12 partially illustrates the pullout portions of the word lines WL0 to WL5 in the string units SU within the block BLK.

As illustrated in FIG. 12, the pullout portions of the word lines WL are provided in three rows. Specifically, the pullout portions of the word lines WL0 to WL2 are aligned in the X direction. The pullout portion of the word lines WL3 to WL5 are arranged adjacently to the pullout portions of the word lines WL0 to WL2 in the Y direction. In other words, the pullout portions of the word lines WL0 and WL2 and the pullout portions of the word lines WL3 to WL5 are each formed in a step shape in the X direction, and the wiring layers for three steps are formed respectively in the pullout portions of the word lines WL0 to WL2 and in the pullout portions of the word lines WL3 to WL5. Thus, the word lines WL are formed in a step shape of three rows.

In the pullout region HR, the pullout portion of the word line WL0 is formed by narrowing the end portion of the word line WL1 more than the end portion of the word line WL0 in width. Similarly, the pullout portion of the word line WL1 is formed by narrowing the end portion of the word line WL2 more than the end portion of the word line WL1 in width. In the cell region CR, the widths of the word lines WL0 to WL2 are identical and the word lines WL0 to WL2 overlap each other.

In each of the string units SU, the contact plugs CP provided in the pullout portions of the word lines WL arranged in the X direction are offset from each other in the Y direction. Specifically, the contact plugs CP-1 to CP-3 are respectively provided in the pullout portions of the word lines WL0 to WL2. The contact plugs CP-1 to CP-3 are arranged in the first direction D1 in the string unit SU0 and arranged in the second direction D2 in the string unit SU1. Similarly, the contact plugs CP-1 to CP-3 corresponding to the word lines WL3-WL5 are offset from each other in the Y direction.

The contact plugs CP corresponding to the pullout portion of the word line WL are arranged across the string units SU along a straight line in the X direction. In other words, the contact plugs CP arranged in the X direction among the string units SU do not contain any plugs corresponding to the different word line WL.

The short wiring SW is provided over the contact plugs CP corresponding to the respective word lines WL. Specifically, the wiring SW0 is provided to couple the contact plugs CP-1 corresponding to the word line WL0 in each of the string units SU in common, the wiring SW1 is provided to couple the contact plugs CP-2 corresponding to the word line WL1 in each of the string units SU in common, and the wiring SW2 is provided to couple the contact plugs CP-3 corresponding to the word line WL2 in each of the string units SU in common. Similarly, the wirings SW3 to SW5 are respectively provided to couple the respective contact plugs CP-1 to CP-3 corresponding to the respective word lines WL3 to WL5 in each of the string units SU in common. The other wirings SW have the same structure.

In the above structure, for example, the wiring layers SW are formed on the same layer and the respective contact plugs CP are formed to the layer of the same level of height. The contact plugs CP and the wiring layer SW may be directly coupled together or they may be coupled through the word line contacts WLC.

[2-2] Effect of Second Embodiment

The effect of the second embodiment will be described. The semiconductor memory device 1 according to the second embodiment can obtain the same effect as that of the first embodiment. Further, the semiconductor memory device 1 according to the second embodiment can suppress the number of the wiring layers necessary for electrically connecting the word line WL across the string units SU. The details will be described as below.

The semiconductor memory device with the memory cells stacked increases the number of the stacked word lines according to an increase in the stacked memory cells. Then, in order to suppress the increase in the circuit area, the pullout portions of the word lines are formed in a step shape of three rows.

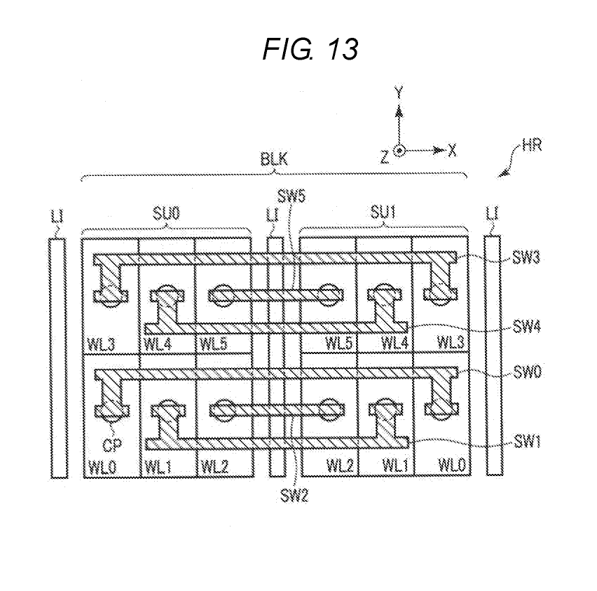

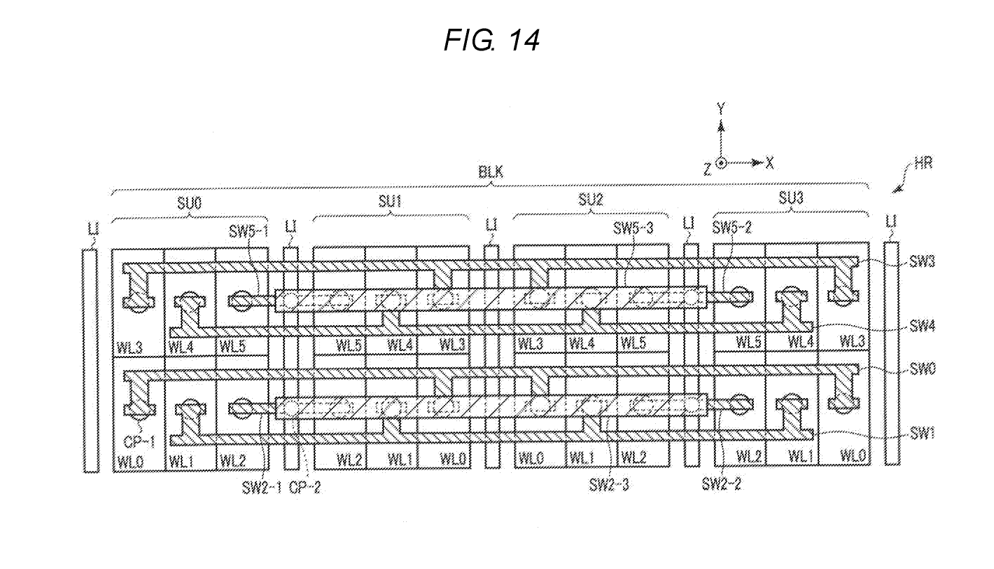

For example, when the pullout portions of the word lines WL are formed in a step shape of three rows, the structure illustrated in FIGS. 13 and 14 may be used in the comparative example. The structure illustrated in FIG. 13 corresponds to the case of the two string units SU included in one block BLK and the structure illustrated in FIG. 14 corresponds to the case of the four string units SU included in one block BLK.

In the case of the structure illustrated in FIG. 13, the contact plugs CP corresponding to the word lines WL forming a step in the X direction (bit line direction) are formed along a straight line in the X direction. As described in the first embodiment, a margin for avoiding a connection with the non-corresponding contact plugs CP is necessary, in addition to the wiring width for the short wiring SW.

Further, in the case of three and more string units SU, like the structure illustrated in FIG. 14, the short wirings SW coupling the adjacent word lines are coupled through an additional upper wiring layer. For example, as the short wiring corresponding to the word lines WL2, the short wiring SW2-1 is provided between the string units SU0 and SU1 and the short wiring SW2-2 is provided between the string units SU2 and SU3, and the short wiring SW2-3 is provided between the short wirings SW2-1 and SW2-2. The short wiring SW2-3 is coupled to the short wirings SW2-1 and SW2-2 through the contact plugs CP-2 provided on the short wirings SW2-1 and SW2-2.

As mentioned above, when the pullout portions of the word lines WL are formed in a step shape of three rows and one block BLK contains three or more string units SU, the wiring layers consisting of two layers are necessary in order to form the three short wirings SW corresponding to the three word lines whose pullout portions are arranged in the bit line direction.

On the other hand, the wiring for coupling the word lines WL to the row decoder is provided in the Y direction. The number of the wirings is determined according to the number of the word lines WL and the select gate lines SGD and SGS and their controlling method. As illustrated in FIG. 14, since the short wirings SW are provided along the X direction, the short wirings SW cross the wirings for coupling the word lines WL to the row decoder, sometimes disturbing their arrangement. Therefore, when the number of the wiring layers necessary for the short wirings SW increases, additional wiring layers may be occasionally required in order to arrange a desired number of the wirings for coupling the word lines WL to the row decoder.

According to the second embodiment, in the semiconductor memory device 1 in which the pullout portions of the word lines WL are formed in a step shape of three rows, the contact plugs CP provided on the pullout portions of the word lines formed in a step shape in the bit line direction are offset from each other in the word line direction. According to this, as illustrated in FIG. 12, the contact plugs CP arranged in the bit line direction are adapted so that the short wirings SW can be formed in a straight line shape.

According to this, similarly to the first embodiment, the design of the short wirings SW can be simplified and the difficulty of the patterning during lithography is reduced. In other words, the semiconductor memory device 1 according to the embodiment can suppress the defects caused during lithography at the manufacturing time, hence to improve the yield.

Further, the semiconductor memory device 1 according to the embodiment can form the short wirings SW in one wiring layer even when the pullout portions of the word lines WL are formed in a step shape of three rows. In other words, the semiconductor memory device 1 according to the embodiment can suppress the number of the wiring layers necessary for electrically connecting the word lines WL across the string units SU and reduce the manufacturing cost of the semiconductor memory device 1.

### [3] Third Embodiment

A semiconductor memory device 1 according to a third embodiment will be described. In the third embodiment, the step shape of the word lines WL in the wiring pullout region described in the first embodiment is changed from the step shape of two rows to the step shape of four rows. Hereinafter, a different point from the first and the second embodiments will be described.

[3-1] Structure of Third Embodiment

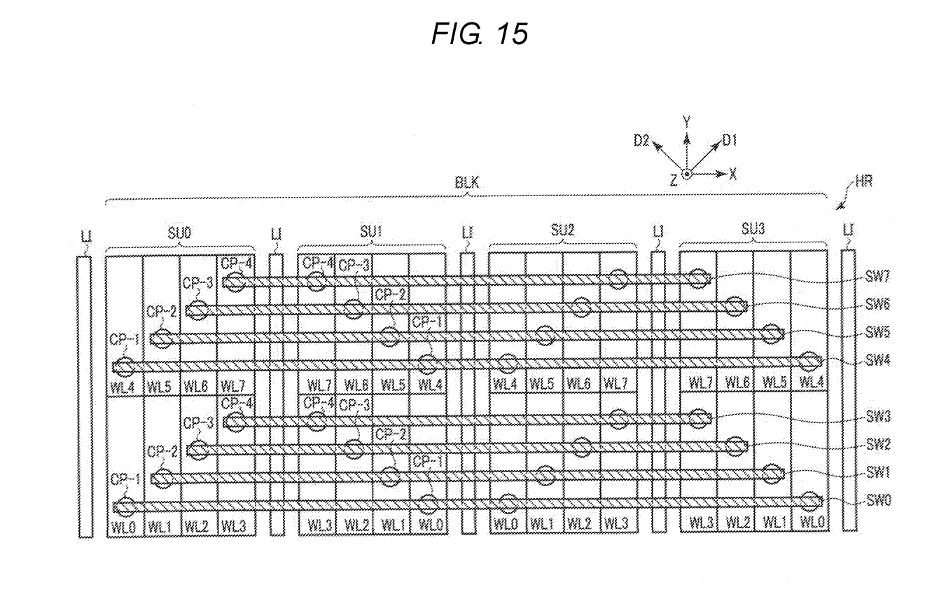

At first, with reference to FIG. 15, the layout of the memory cell array 11 in the pullout region HR will be described. FIG. 15 partially illustrates the pullout portions of the word lines WL0 to WL7 in each of the string units SU within the block BLK.

As illustrated in FIG. 15, the pullout portions of the word lines WL are provided in four rows. Specifically, the pullout portions of the word lines WL0 to WL3 are arranged in the X direction and the pullout portions of the word lines WL4 to WL7 are arranged adjacently to the pullout portions of the word lines WL0 to WL3 in the Y direction. In other words, the pullout portions of the word lines WL0 to WL3 and the pullout portions of the word lines WL4 to WL7 are respectively formed in a step shape in the X direction, and steps for four wiring layers are formed in the pullout portions of the word lines WL0 and WL3 and in the pullout portions of the word lines WL4 to WL7. Thus, the word lines WL are formed in a step shape of four rows.

In the pullout region HR, the pullout portion of the word line WL0 is formed by narrowing the end portion of the word line WL1 more than the end portion of the word line WL0 in width. Similarly, the pullout portion of the word line WL1 is formed by narrowing the end portion of the word line WL2 more than the end portion of the word line WL1 in width and the pullout portion of the word line WL2 is formed by narrowing the end portion of the word line WL3 more than the end portion of the word line WL2 in width. Further, in the cell region CR, the widths of the word lines WL0 to WL3 are identical and the word lines WL0 to WL3 overlap with each other.

In each of the string units SU, the contact plugs CP provided in the pullout portions of the word lines WL arranged in the X direction are offset from each other in the Y direction. Specifically, the contact plugs CP-1 to CP-4 are respectively provided in the pullout portions of the word lines WL0 to WL3. The contact plugs CP-1 to CP-4 are arranged along the first direction D1 in the string unit SU0 and arranged along the second direction D2 in the string unit SU1. Similarly, the contact plugs CP-1 to CP-4 corresponding to the word lines WL4-WL7 are offset from each other in the Y direction.

The contact plugs CP corresponding to the pullout portions of the word line WL are arranged in series in the X direction. In other words, the contact plugs CP are aligned in the X direction across the string units SU and do not contain any contact plugs corresponding to the different word line WL.

The short wiring SW is provided over the contact plugs CP corresponding to the respective word lines WL. Specifically, the wiring SW0 is provided to couple the contact plugs CP-1 corresponding to the word line WL0 in each of the string units SU in common, the wiring SW1 is provided to couple the contact plugs CP-2 corresponding to the word line WL1 in each of the string units SU in common, the wiring SW2 is provided to couple the contact plugs CP-3 corresponding to the word line WL2 in each of the string units SU in common, and the wiring SW3 is provided to couple the contact plugs CP-4 corresponding to the word line WL3 in each of the string units SU in common. Similarly, the wirings SW4 to SW7 are respectively provided to couple the respective contact plugs CP-1 to CP-4 corresponding to the respective word lines WL4 to WL7 of each of the string units SU in common.

In the above structure, for example, the wiring layers SW are formed in the same layer and the respective contact plugs CP are formed to the layer of the same level of height. The contact plugs CP and the wiring layer SW may be directly coupled together or they may be coupled through the word line contacts WLC.

[3-2] Effect of Third Embodiment

The effect of the third embodiment will be described. The semiconductor memory device 1 according to the third embodiment can obtain the same effect as that of the second embodiment. The details will be described in the below.

The semiconductor memory device with the memory cells stacked is formed to make the pullout portion of the word lines in a step shape of four rows in order to suppress the increase in the circuit area.

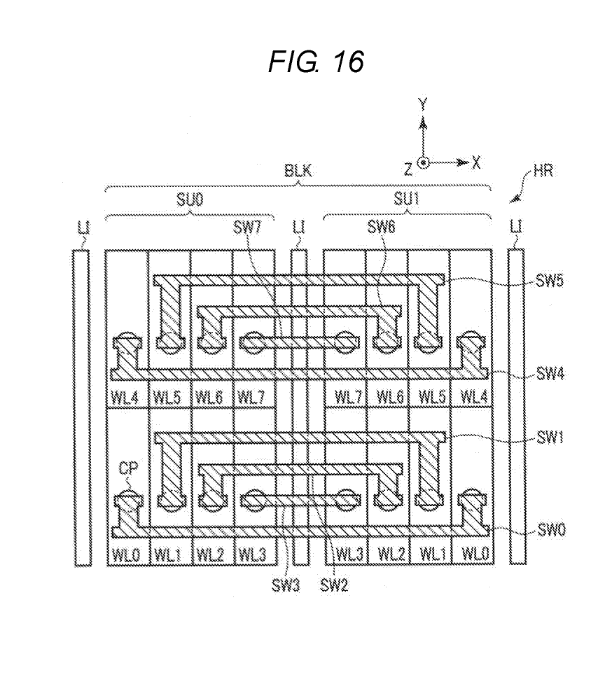

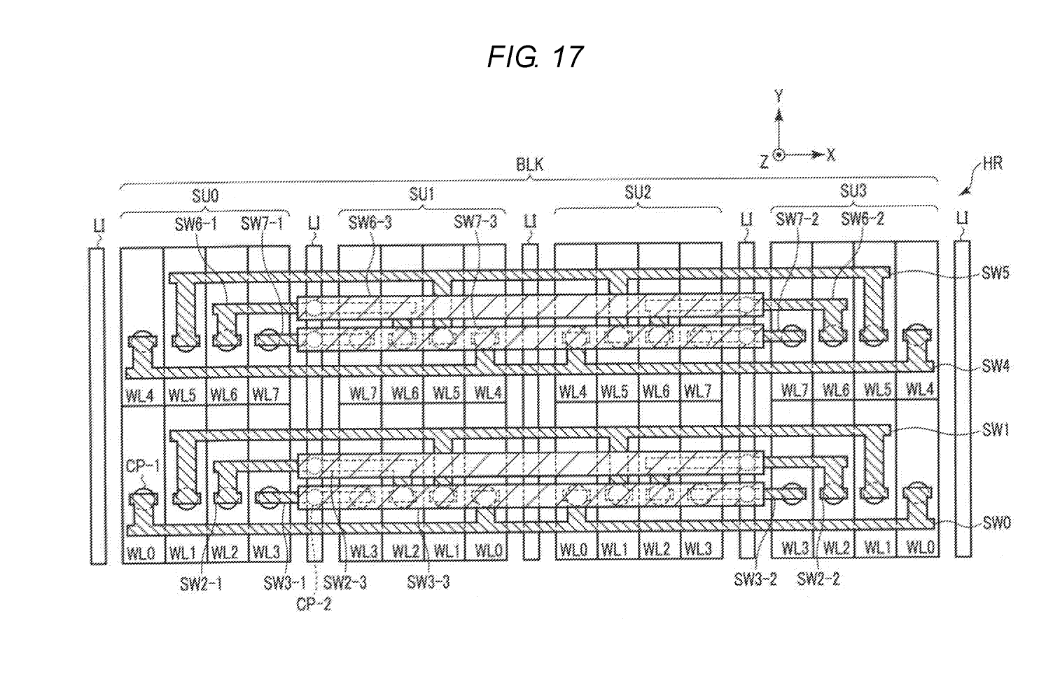

For example, when the pullout portion of the word lines WL are formed in a step shape of four rows, the structure illustrated in FIGS. 16 and 17 may be used in a comparative example. The structure illustrated in FIG. 16 corresponds to the case of the two string units SU included in one block BLK and the structure illustrated in FIG. 17 corresponds to the case of the four string units SU included in one block BLK.

In the case of the structure illustrated in FIG. 16, the contact plugs CP corresponding to the word lines WL forming a step in the X direction (bit line direction) are formed along a straight line in the X direction. In this case, as mentioned above, a margin for avoiding a connection with the non-corresponding contact plugs CP is necessary, in addition to the wiring width for the short wiring SW.

Further, in the case of three or more string units SU, like the structure illustrated in FIG. 17, the short wirings SW coupling the adjacent word lines are coupled through an additional upper wiring layer. For example, as the short wirings corresponding to the word lines WL2 and WL3, the short wirings SW2-1 and SW3-1 are provided between the string units SU0 and SU1 and the short wirings SW2-2 and SW3-2 are provided between the string units SU2 and SU3, further the short wiring SW2-3 for coupling the short wirings SW2-1 and SW2-2 and the short wiring SW3-3 for coupling the short wirings SW3-1 and SW3-2 are provided. The short wiring SW2-3 is coupled to the short wirings SW2-1 and SW2-2 through the contact plugs CP-2 provided on the short wirings SW2-1 and SW2-2, and the short wiring SW3-3 is coupled to the short wirings SW3-1 and SW3-2 through the contact plugs CP-2 provided on the short wirings SW3-1 and SW3-2.

As mentioned above, when the pullout portions of the word lines WL are formed in a step shape of four rows and one block BLK contains three or more string units SU, the wiring layers consisting of two layers are necessary in order to form the four short wirings SW corresponding to the four word lines whose pullout portions are arranged in the bit line direction.

On the other hand, according to the third embodiment, in the semiconductor memory device 1 where the pullout portions of the word lines WL are formed in a step shape of four rows, the contact plugs CP provided on the pullout portions of the word lines formed in a step shape in the bit line direction are offset with each other in the word line direction. As illustrated in FIG. 15, the contact plugs CP arranged in the bit line direction are adapted so that the short wirings SW can be formed in a straight line shape.

According to this, the semiconductor memory device 1 according to the embodiment can obtain the same effect as that of the second embodiment even in the case of the pullout portions of the word lines WL having a step shape of four rows.

### [4] Fourth Embodiment

A semiconductor memory device 1 according to a fourth embodiment will be described. In the fourth embodiment, a shallow slit is formed in the cell region, in one string unit SU having been described in the first embodiment, hence to divide the select gate line SGD. Hereinafter, a different point from the first to the third embodiments will be described.

[4-1] Structure of Fourth Embodiment

[4-1-1] Plan Surface and Cross Sectional Structure of Memory Cell Array 11

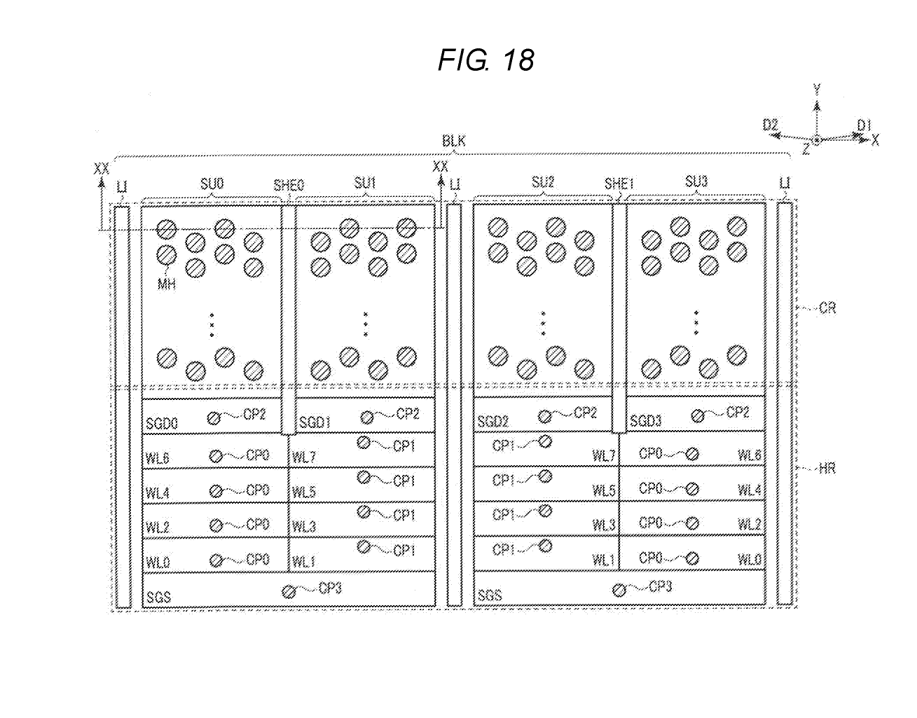

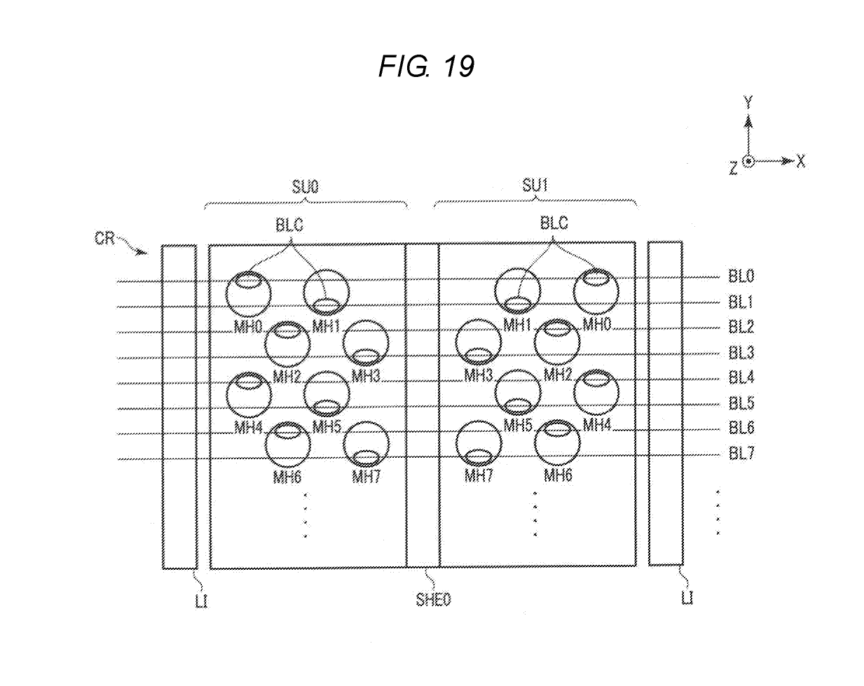

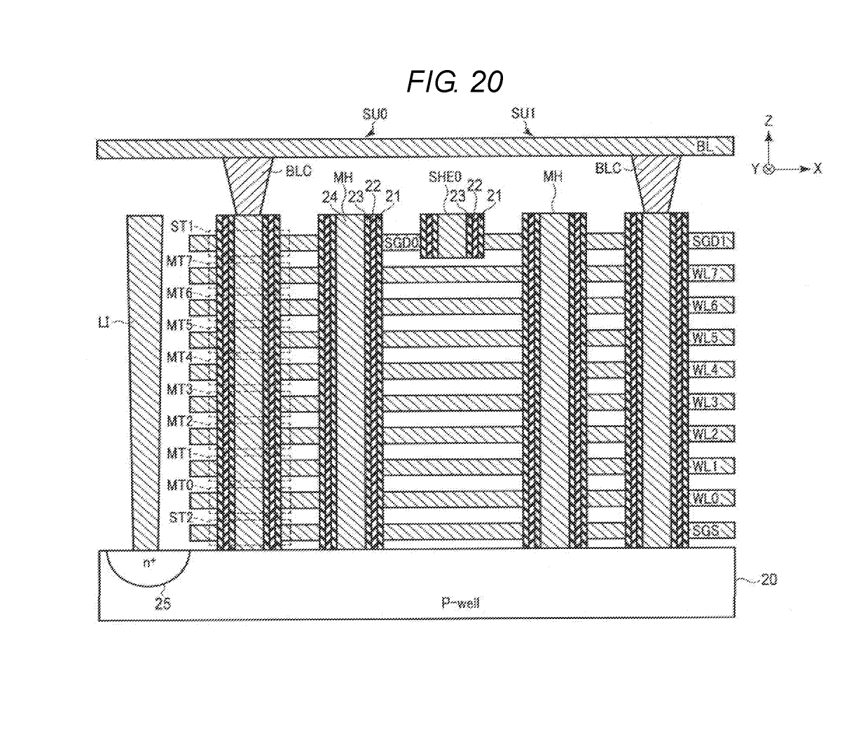

At first, with reference to FIGS. 18 to 20, the plan surface and the cross sectional structure of the memory cell array 11 will be described. FIG. 18 illustrates the plan layout of one block BLK included in the memory cell array 11, FIG. 19 illustrates the plan layout in the cell region CR in the string units SU0 and SU1, and FIG. 20 illustrates the cross section taken along the line XX-XX of FIG. 18.

As illustrated in FIG. 18, the plan layout of the memory cell array 11 in the semiconductor memory device 1 according to the fourth embodiment is different from FIG. 4 of the first embodiment in that two string units SU are formed in an area divided by the contact plugs LI within one block BLK.

Specifically, for example, in the string units SU0 and SU1, the select gate line SGS and the word lines WL0 to WL7 are shared and the select gate line SGD is divided by the cell array slit SHE0. This cell array slit SHE0 is provided in a line shape between the string units SU0 and SU1 along the Y direction and the length in the Y direction is longer than the select gate line SGD in the Y direction and shorter than the word lines WL6 and WL7 in the Y direction.

As illustrated in FIG. 19, the detailed plan layout in the string units SU0 and SU1 is the same as that in FIG. 5 of the first embodiment except that the cell array slit SHE0 is provided between the string units SU0 and SU1.

The cross sectional structure in the cell region CR including this cell array slit SHE is illustrated in FIG. 20. As illustrated in FIG. 20, the cell array slit SHE0 is formed to divide the select gate line SGD, along the Z direction. Specifically, the wiring layer of the select gate line SGD corresponding to the string units SU0 and SU1 is divided by the slit SHE. According to this, the select gate lines SGD0 and SGD1 are formed respectively for the string units SU0 and SU1.

On the lateral side of the cell array slit SHE, a block insulating film 21, an insulating film (charge storage layer) 22, and a tunnel oxide film 23 are sequentially formed. Further, the semiconductor material 24 including the conductive material is filled in the inner portion from the tunnel oxide film 23. In short, the cell array slit SHE has the same structure as, for example, that of the semiconductor pillar MH. The other cross sectional structure is the same as that of FIG. 6 having been described in the first embodiment.

As mentioned above, in the semiconductor memory device 1 according to the fourth embodiment, the two string units SU sharing the word lines WL are formed in every area divided by the contact plugs LI within one block BLK.

In the case of this structure, the short wiring SW in the pullout region HR is provided in every area divided by the contact plugs LI. For example, referring to FIG. 18, the short wirings SW are respectively provided between a set of the string units SU0 and SU1 sharing the word lines WL and between a set of the string units SU2 and SU3 sharing the word lines WL. The structure of providing the short wiring SW is the same as that of the first embodiment.

In the above structure, although the two string units SU are formed in an area divided by the contact plugs LI within one block BLK, it is not limited to this. For example, a plurality of cell array slits SHE may be provided in the area divided by the contact plugs LI. In this case, three or more string units SU can be formed in the area divided by the contact plugs LI.

FIG. 18 illustrates the case of forming the word lines WL in a step shape of two rows in the pullout region HR; however, it is not limited to this. Also in the semiconductor memory device 1 using the cell array slit SHE, the second and the third embodiments can be applied. Alternatively, the word lines WL can be formed in a step shape of four rows.

Further, a dummy semiconductor pillar MH may be formed in the lower portion of the slit SHE in the embodiment. When forming this dummy semiconductor pillar MH, the slit SHE may be designed to separate the gate of a dummy memory cell transistor provided in the dummy semiconductor pillar MH.

Further, the shape of the word line WL and the select gate line SGS may be partially cut off by the slit SHE and as far as the above lines are not separated into two when the slit SHE is formed, any shape will do.

Further, the bottom of the slit SHE may reach the word line WL in the lower layer. For example, even when the slit SHE penetrates the word line WL7, arriving at the word line WL6, unless the end portion of the word line WL7 is divided in the pullout region HR, this is acceptable.

Further, the slit SHE may exclude the semiconductor material 24. For example, when the width of the slit SHE is narrow, the slit SHE may be completely filled with the internal block insulating film 21, the charge storage layer 22, and the tunnel oxide film 23 when they are formed.

FIG. 20 is a schematic view and the arrangement of the semiconductor pillar MH and the cell array slit SHE may be deviated with each other and not at the regular intervals.

[4-2] Effect of Fourth Embodiment

The effect of the fourth embodiment will be described. In the semiconductor memory device 1 according to the fourth embodiment, the first and the third embodiments can be applied also in the case of forming two string units SU in an area divided by the contact plugs LI within one block BLK. The details will be described in the below.

In the semiconductor memory device with the memory cells stacked, the string units sharing the word lines WL and the select gate line SGS can be formed by dividing the select gate line SGD using the cell array slit SHE.

According to the embodiment, the first to the third embodiments can be applied to the semiconductor memory device 1 with the string units SU formed by using this cell array slit SHE. The structure of the first embodiment is applicable even when the select gate line SGD is divided by the slit SHE. Similarly, this structure can be applied also to the structure of the second and the third embodiments. In other words, the semiconductor memory device 1 can freely design the step shape of any number of rows in the pullout portions of the word lines WL, in the several string units SU sharing the word lines WL.

According to this, the semiconductor memory device 1 according to the embodiment can obtain the same effect as that of the first to the third embodiments.

### [5] Fifth Embodiment

Next, a semiconductor memory device 1 according to a fifth embodiment will be described. In the fifth embodiment, a groove for coupling the select gate line SGD to the circuit under the memory cell array is provided in the wiring pullout region of the memory cell array 11 having been described in the first embodiment. Hereinafter, a different point from the first to the fourth embodiments will be described.

[5-1] Structure of Fifth Embodiment

[5-1-1] Plan Surface and Cross Sectional Structure of Memory Cell Array 11

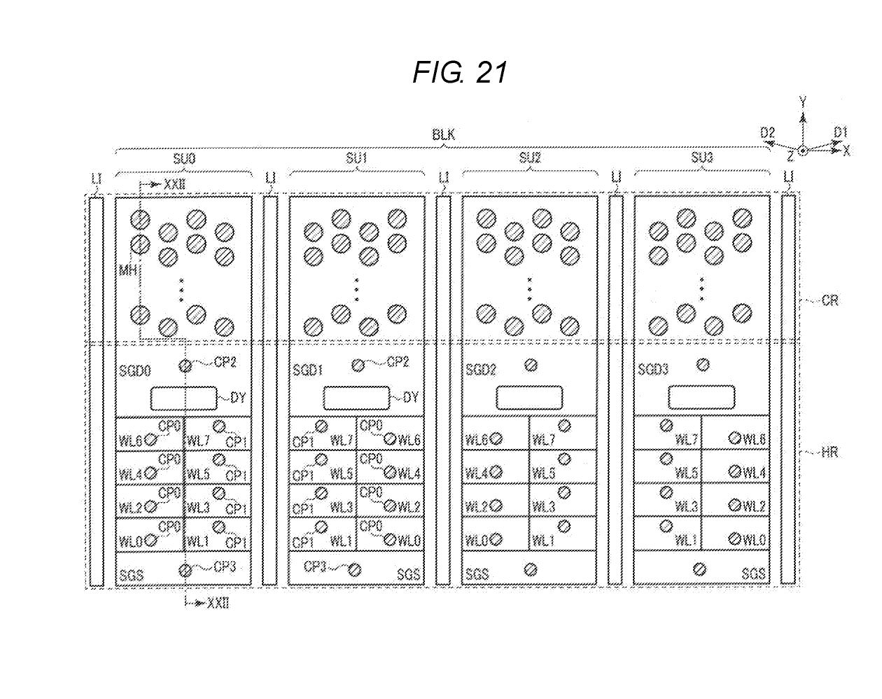

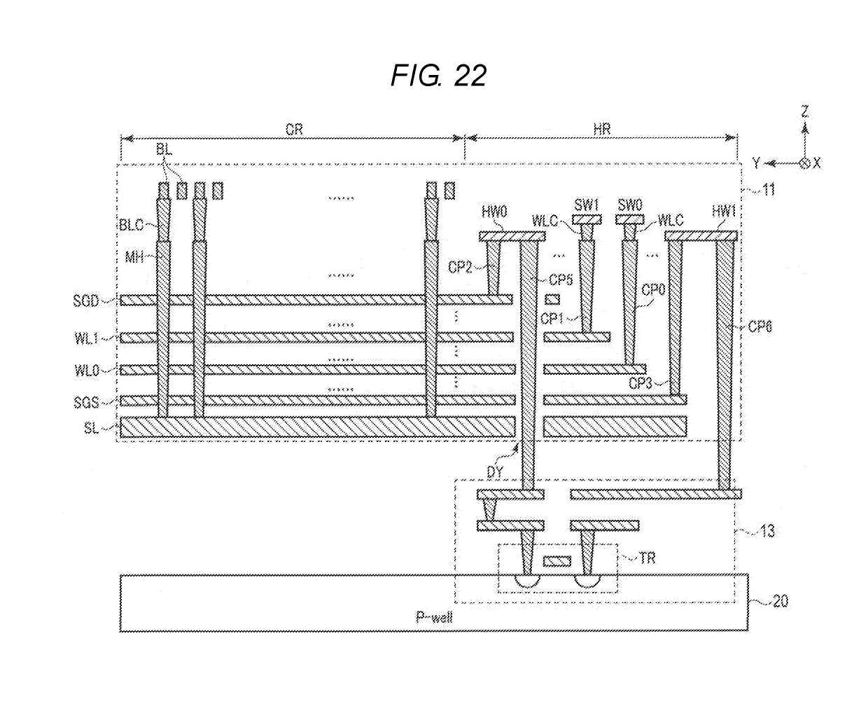

With reference to FIGS. 21 and 22, the plan surface and cross sectional structure of the memory cell array 11 will be described. FIG. 21 illustrates the plan layout of one block BLK included in the memory cell array 11 and FIG. 22 illustrates the cross section taken along the line XXII-XXII of FIG. 21. The cross section illustrated in FIG. 22 shows all the elements positioned in the depth side from the paper surface, by the solid line.

As illustrated in FIG. 21, the plan layout of the memory cell array 11 in the semiconductor memory device 1 according to the fifth embodiment is different from that of FIG. 4 having been described in the first embodiment in that a groove DY is provided in the end portion of the select gate line SGD and between the contact plug CP2 and the word lines WL.

Further, as illustrated in FIG. 22, the semiconductor memory device 1 according to the embodiment is provided with the row decoder 13 between the memory cell array 11 and the P-type well region 20. FIG. 22 illustrates one transistor TR, by way of example, included in the row decoder 13. In this case, the memory cell array 11 is formed over the wiring layer corresponding to the source line SL. The source line SL is formed of a conductive material and provided with the same function as that of the source line CELSRC shown in FIG. 6.

The groove DY is formed in a way of going through the select gate line SGD in the uppermost layer to the source line SL. This groove DY is filled with an interlayer insulating film (not illustrated). In the area illustrated in FIG. 22, the conductive layers working as the word lines WL, the select gate line SGS, and the source line SL are divided into two areas by the groove DY; however, they are coupled together in an area not illustrated.

The wiring HW0 electrically coupled to the select gate line SGD is coupled to the row decoder 13 in the lower layer through the contact plug CP5 passing through the groove DY. The wiring HW1 electrically coupled to the select gate line SGS is coupled to the row decoder 13 in the lower layer through the contact plug CP6 passing through the end portion of the pullout region HR. Similarly, the word lines WL are coupled to the row decoder 13 in the lower layer together with the short wirings SW through the wiring layers and the contact plugs CP (not illustrated).

[5-2] Effect of Fifth Embodiment

Next, the effect of the fifth embodiment will be described. Also when forming the groove for coupling with the row decoder formed in the lower layer in the string unit SU, the first to the fourth embodiments can be applied to the semiconductor memory device 1 according to the fifth embodiment. The details will be described in the below.

The semiconductor memory device occasionally forms the row decoder between the semiconductor substrate and the memory cell array in order to suppress the circuit area. In this case, for example, a groove passing through the wiring layers corresponding to the select gate line SGD, the word line WL, and the select gate line SGS may be provided in the area of drawing the wirings in the memory cell array. In this structure, for example, the select gate line SGD is coupled to the circuit under the memory cell array through the contact plug passing through the groove.

In the embodiment, the first to the fourth embodiments are applied to the semiconductor memory device 1 provided with this groove. The structure of the first embodiment can be applied also to the case of coupling the select gate line SGD to the circuit of the lower layer through the groove formed in the select gate line SGD as illustrated in FIG. 21. Similarly, the structure can be applied also to the structures of the second to the fourth embodiments. In other words, the structure of the pullout region HR like the first to the third embodiments and the structure of the cell region CR like the fourth embodiment can be applied also to the case of forming this groove.

According to this, the semiconductor memory device 1 according to the embodiment can obtain the same effect as that of the first to the fourth embodiments.

### [6] Modified Examples

The semiconductor memory device <1, FIG. 1> according to the embodiments includes a memory cell array <11, FIG. 1>. The memory cell array includes a first region <CR, FIG. 4> including a plurality of memory cells, where a plurality of wiring layers are stacked over a semiconductor substrate, and a second region <HR, FIG. 4> including end portions of the wiring layers and a plurality of plugs <CP, FIG. 4> provided on the end portions, which is aligned with the first region along a first direction <Y direction, FIG. 4> that is an inward direction of the semiconductor substrate. The wiring layers include first and second wiring layers <WL0 in SU0&SU1, FIG. 9> separated with each other, and third and fourth wiring layers <WL1 in SU0&SU1, FIG. 9> separated with each other, provided over the first and the second wiring layers. In the second region, the first wiring layer includes a first surface that is a part of a top surface of the first wiring layer and does not overlap with the third wiring layer, the second wiring layer includes a second surface that is a part of a top surface of the second wiring layer and does not overlap with the fourth wiring layer, and the third and the fourth wiring layers include third and fourth surfaces that are a part of top surfaces of the third and fourth wiring layers. The plugs include first to fourth plugs <CP0&CP1 in SU0&SU1, FIG. 9> respectively in contact with the first to the fourth surfaces. The second region includes a fifth wiring layer <WS0, FIG. 8> in contact with the first and the second plugs <CP0 in SU0&SU1, FIG. 8> and further a sixth wiring layer <WS1, FIG. 8> in contact with the third and the fourth plugs <CP1 in SU0&SU1, FIG. 8>. The first and the third surfaces are arranged in the inward direction of the semiconductor substrate along a second direction <X direction, FIG. 8> different from the first direction. The second and the fourth surfaces are arranged in the second direction. The first and the third plugs are arranged in the inward direction of the semiconductor substrate along a third direction <D1, FIG. 8> crossing the first and the second directions. The second and the fourth plugs are arranged in the inward direction of the semiconductor substrate along a fourth direction <D2, FIG. 8> crossing the first and the second directions.

According to this, a semiconductor memory device capable of improving the yield can be provided.

The embodiments are not limited to the above first to fifth embodiments but various modifications are possible. For example, in the embodiments, the adjacent string units SU are formed in a line symmetry with the Y direction as an axis of symmetry; however, the adjacent string units SU are not limited to this structure. The adjacent string units may be formed in the same structure.

In the embodiments, within the memory cell array 11, a plurality of semiconductor pillars MH may be formed in a staggered shape of any number of rows, but the structure is not limited to the above. For example, the semiconductor pillars MH may be arranged in a staggered shape of nine rows. Alternatively, the semiconductor pillars MH may be arranged in a matrix shape.

Although the above embodiments have been described, by way of example, in the case of electrically coupling the upper wiring layer to the lower wiring layer or the substrate through one or two contact plugs, it is not limited to this. When coupling the upper layer to the lower layer through a contact plug, a plurality of contact plugs may be used. Further, a wiring may be provided between the contact plugs.

Although the above embodiments have been described, by way of example, in the case of arranging the contact plugs CP provided in the pullout portions of the word lines formed in a step shape in the bit line direction, in a way of deviating them in the word line direction, in the semiconductor memory device 1 with the pullout portions of the word lines WL formed in a step shape of several rows, it is not limited to this. For example, as illustrated in FIG. 11, also when the contact plugs provided in the pullout portions of the word lines WL formed in a step shape of two rows are arranged on a straight line along the X direction, the contact plugs coupled to the short wiring SW may be offset in the word line direction using the wiring layer between the upper end of the semiconductor pillar MH and the wiring layer corresponding to the short wiring SW. Also in this case, since the short wiring SW can be formed in a straight line shape, the same effect as that of the above embodiments can be obtained.

Further, in the above embodiments, the structure of the wiring layers in the pullout region HR is not limited to the above. For example, although in the above embodiments, only the word lines WL form the steps of several rows, the word lines WL including the wiring layers of the select gate lines SGD and SGS may form the steps of several rows.

The arrangement of the select gate lines SGD and SGS and the pullout portions of the word lines WL may be set arbitrarily. For example, the word lines WL of the odd number may be exchanged with the word lines WL of the even number, in the structure of the pullout portions of the word lines WL having been described in the first embodiment. Alternatively, the pullout portions of the word lines WL may be formed in a step shape of five rows or more.

Further, in the first embodiment, such a description has been made that the number of the pullout portions formed by the word lines WL in the bit line BL direction (X direction) is identical to the number of the wiring layers overlapping with the pullout portions aligned in the bit line BL direction and provided in a straight line shape, between the contact plugs LI; however, this is not limited to the first embodiment. For example, like the second embodiment, when the number of the pullout portions formed by the word lines WL in the bit line BL direction is three, the number of the wiring layers overlapping with the pullout portions aligned in the bit line BL direction and provided in a straight line shape becomes three. This is true for the third embodiment, and also true to the case of forming the word lines WL in a step shape of five rows or more.

Further, in the above embodiments, the memory cell array 11 is provided with one select gate line SGD and one select gate line SGS; however, it is not limited to this, but may be provided with several lines SGD and several lines SGS. The memory cell array 11 may include one or a plurality of dummy word lines.

Further, in the above embodiments, the wiring of the word line WL is pulled out only from one side in the Y direction; however, it is not limited to this. For example, the pullout regions HR may be arranged to sandwich the cell region CR so that the wiring may be pulled out from the both sides in the Y direction. In this case, the above embodiments can be applied to the structure of the pullout region HR.

Further, although the above embodiments have been described, byway of example, in the case of forming each wiring layer corresponding to each of the select gate lines SGD and SGS by one layer, is not limited to this. Each wiring layer corresponding to each of the select gate lines SGD and SGS may be formed in one or more layers. In the select transistor ST2, when the wiring layer corresponding to the select gate line SGS includes two or more layers, one of the layers may be electrically coupled to the gate similarly to the memory cell transistor MT and the remaining layer or layers may have the different gate input in every NAND string NS.

Further, the NAND string NS may include a dummy memory cell transistor MT. In this case, the dummy word line WL may be provided, for example, between the select gate line SGS and the word line WL0 or between the select gate line SGD and the word line WL7.

In the above description, “coupling” means electrical connection, including not only a direct connection but also a connection through some element.

The memory cell array 11 may be formed to have other structures. The other structures are disclosed, for example, in U.S. patent application Ser. No. 12/407,403, filed Mar. 19, 2009, titled “Three Dimensional Stacked Nonvolatile Semiconductor Memory,” in U.S. patent application Ser. No. 12/406,524, filed Mar. 18, 2009, titled “Three Dimensional Stacked Nonvolatile Semiconductor Memory,” in U.S. patent application Ser. No. 12/679,991, filed Mar. 25, 2010, titled “Non-volatile Semiconductor Storage Device and Method of Manufacturing The Same,” and in U.S. patent application Ser. No. 12/532,030, filed Mar. 23, 2009, titled “Semiconductor Memory and Method for Manufacturing Same”. The entire contents of these patent applications are incorporated by reference herein.

In the above embodiments, the block BLK may not be the unit of data erasing. Alternative, erasing operations employing other unit of data erasing may be used, e.g., as disclosed in U.S. patent application Ser. No. 13/235,389, filed Sep. 18, 2011, titled “Nonvolatile Semiconductor Memory Device” and U.S. patent application Ser. No. 12/694,690, filed Jan. 27, 2010, titled “Non-volatile Semiconductor Storage Device.” The entire contents of these patent applications are incorporated by reference herein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array that includes a first region including a plurality of first memory cells and a plurality of first wiring layers stacked over a semiconductor substrate, and a second region including a plurality of second memory cells and a plurality of second wiring layers stacked over the semiconductor substrate, the first and second wiring layers each including a wiring layer at a first level above the substrate and a wiring layer at a second level above the substrate, wherein
end portions of each of the first wiring layers and the second wiring layers extend in a first direction into a wiring pullout region, such that each of the first and second level wiring layers of both the first and second wiring layers has an exposed upper surface, and
in each of the first wiring layers and the second wiring layers, the exposed upper surfaces of the first and second level wiring layers are adjacent in a second direction crossing the first direction; and
first and second contacts arranged respectively on the exposed surfaces of the first and second level wiring layers of each of the first and second wiring layers, such that the first contacts and the second contacts are arranged respectively along first and second lines that extend in the second direction and are spaced apart in the first direction.

2. The device according to claim 1, further comprising:
a first conductive line coupled to the first contacts and extending in the second direction; and
a second conductive line coupled to the second contacts and extending in the second direction.

3. The device according to claim 2, wherein the first and second conductive lines are at a same level above the substrate.

4. The device according to claim 1, wherein
the first and second wiring layers each further include a wiring layer at a third level above the substrate and a wiring layer at a fourth level above the substrate, end portions of each of the first wiring layers and the second wiring layers extending in the first direction into the wiring pullout region, such that each of the third and fourth level wiring layers of both the first and second wiring layers has an exposed upper surface, and
in each of the first wiring layers and the second wiring layers, the exposed upper surfaces of the third and fourth level wiring layers are adjacent in the second direction, and the exposed upper surfaces of the first and third level wiring layers are adjacent and the exposed upper surfaces of the second and fourth level wiring layers are adjacent, in the first direction.

5. The device according to claim 4, further comprising:
a third contact arranged on the exposed surface of the third level wiring layer of each of the first and second wiring layers; and
a fourth contact arranged on the exposed surface of the fourth level wiring layer of each of the first and second wiring layers, wherein
the third contacts and the fourth contacts are arranged respectively along third and fourth lines that extend in the second direction and are spaced apart in the first direction.

6. The device according to claim 5, wherein the memory cell array further includes:
a third region including a plurality of third memory cells and a plurality of third wiring layers stacked over the semiconductor substrate, the third wiring layer including wiring layers at the first, second, third, and fourth levels above the substrate, end portions of third wiring layers extending in the first direction into the wiring pullout region, such that each of the first, second, third, and fourth level wiring layers of the third wiring layers has an exposed upper surface;
a fourth region including a plurality of fourth memory cells and a plurality of fourth wiring layers stacked over the semiconductor substrate, the fourth wiring layer including wiring layers at the first, second, third, and fourth levels above the substrate, end portions of fourth wiring layers extending in the first direction into the wiring pullout region, such that each of the first, second, third, and fourth level wiring layers of the fourth wiring layers has an exposed upper surface, wherein
in each of the third wiring layers and the fourth wiring layers, the exposed upper surfaces of the third and fourth level wiring layers are adjacent in the second direction, and the exposed upper surfaces of the first and third level wiring layers are adjacent and the exposed upper surfaces of the second and fourth level wiring layers are adjacent, in the first direction.

7. The device according to claim 6, further comprising:
first and second contacts arranged respectively on the exposed surfaces of the first and second level wiring layers of each of the third and fourth wiring layers, such that the first contacts and the second contacts are arranged respectively along the first and second lines; and
third and fourth contacts arranged respectively on the exposed surfaces of the third and fourth level wiring layers of each of the third and fourth wiring layers, such that the third contacts and the fourth contacts are arranged respectively along the third and fourth lines.

8. The device according to claim 5, wherein
in each of the first wiring layers and the second wiring layers, the second level wiring layer is stacked above and the first level wiring layer, the third level wiring layer above the second level wiring layer, and the fourth level wiring layer above the third level wiring layer.

9. The device according to claim 1, further comprising:
a planar contact on the substrate that extends above the substrate and in the first direction to separate the first region and the second region.

10. The device according to claim 1, further comprising:
a planar contact on the substrate that extends above the substrate and in the first direction to separate the first region and the second region.

11. The device according to claim 1, wherein
each of the first and second wiring layers includes a first select gate line, a plurality of word lines above the first select gate line, and a second select gate line above the word lines, and
the first, second, third, and fourth level wiring layers are each one of the word lines.

12. The device according to claim 11, wherein the memory cell array further includes:
a plurality of third memory cells that share the word lines of the first wiring layers with the first memory cells;
a plurality of fourth memory cells that share the word lines of the second wiring layers with the second memory cells;
first, second, third, and fourth select transistors for selecting the first, second, third, and fourth memory cells, respectively; and
first, second, third, and fourth select gate lines coupled to gates of the first, second, third, and fourth select transistors, respectively, wherein
one of the first wiring layers is separated into the first and second select gate lines that are electrically insulated from each other, and one of the second wiring layers is separated into the third and fourth select gate lines that are electrically insulated from each other.

13. A semiconductor memory device comprising:
a memory cell array that includes a first region including a plurality of first memory cells and a plurality of first wiring layers stacked over a semiconductor substrate, and a second region including a plurality of second memory cells and a plurality of second wiring layers stacked over the semiconductor substrate, the first and second wiring layers each including a wiring layer at a first level above the substrate, a wiring layer at a second level above the substrate, and a wiring layer at a third level above the substrate, wherein
end portions of each of the first wiring layers and the second wiring layers extend in a first direction into a wiring pullout region, such that each of the first, second, and third level wiring layers of both the first and second wiring layers has an exposed upper surface, and
in each of the first wiring layers and the second wiring layers, the exposed upper surfaces of the first, second, and third level wiring layers are adjacent in a second direction crossing the first direction; and
first, second, and third contacts arranged respectively on the exposed surfaces of the first, second, and third level wiring layers of each of the first and second wiring layers, such that the first contacts, the second contacts, and the third contacts are arranged respectively along first, second, and third lines that extend in the second direction and are spaced apart from each other in the first direction.

14. The device according to claim 13, further comprising:
a first conductive line coupled to the first contacts and extending in the second direction;
a second conductive line coupled to the second contacts and extending in the second direction; and
a third conductive line coupled to the third contacts and extending in the second direction.

15. The device according to claim 14, wherein the first, second, and third conductive lines are at a same level above the substrate.

16. The device according to claim 13, wherein
in each of the first wiring layers and the second wiring layers, the second level wiring layer is stacked above and the first level wiring layer and the third level wiring layer is stacked above the second level wiring layer.

17. A semiconductor memory device comprising:
a memory cell array that includes a first region including a plurality of first memory cells and a plurality of first wiring layers stacked over a semiconductor substrate, and a second region including a plurality of second memory cells and a plurality of second wiring layers stacked over the semiconductor substrate, the first and second wiring layers each including a wiring layer at a first level above the substrate, a wiring layer at a second level above the substrate, a wiring layer at a third level above the substrate, and a wiring layer at a fourth level above the substrate, wherein
end portions of each of the first wiring layers and the second wiring layers extend in a first direction into a wiring pullout region, such that each of the first, second, third, and fourth level wiring layers of both the first and second wiring layers has an exposed upper surface, and
in each of the first wiring layers and the second wiring layers, the exposed upper surfaces of the first, second, third, and fourth level wiring layers are adjacent in a second direction crossing the first direction; and
first, second, third, and fourth contacts arranged respectively on the exposed surfaces of the first, second, third, and fourth level wiring layers of each of the first and second wiring layers, such that the first contacts, the second contacts, the third contacts, and the fourth contacts are arranged respectively along first, second, third, and fourth lines that extend in the second direction and are spaced apart from each other in the first direction.

18. The device according to claim 17, further comprising:
a first conductive line coupled to the first contacts and extending in the second direction;
a second conductive line coupled to the second contacts and extending in the second direction;
a third conductive line coupled to the third contacts and extending in the second direction; and.
a fourth conductive line coupled to the fourth contacts and extending in the second direction.

19. The device according to claim 18, wherein the first, second, third, and fourth conductive lines are at a same level above the substrate.

20. The device according to claim 17, wherein
in each of the first wiring layers and the second wiring layers, the second level wiring layer is stacked above and the first level wiring layer, the third level wiring layer above the second level wiring layer, and the fourth level wiring layer above the third level wiring layer.
